(19) United States
(12) Patent Application Publication
(10) Pub. No.: US 2020/0402686 A1
(43) Pub. Date: Dec. 24, 2020

(54) SUPERCONDUCTING BLOCK, SUPERCONDUCTING NANOCRYSTAL, SUPERCONDUCTING DEVICE AND A PROCESS THEREOF

(71) Applicant: INDIAN INSTITUTE OF SCIENCE, Bengaluru (IN)

(72) Inventors: Anshu PANDEY, Bengaluru (IN); Dev Kumar THAPA, Bengaluru (IN); Subham Kumar SAHA, Bengaluru (IN)

(73) Assignee: INDIAN INSTITUTE OF SCIENCE, Bengaluru (IN)

(21) Appl. No.: 16/979,113

(22) PCT Filed: Mar. 11, 2019
(86) PCT No.: PCT/IN2019/050198

§ 371 Date: Sep. 8, 2020

(30) Foreign Application Priority Data
Mar. 9, 2018 (IN) 201841008648

(51) Int. Cl. H01B 12/00; H01L 39/08

(52) U.S. Cl. CPC H01B 12/00; B82Y 30/00; H01L 39/08

(57) ABSTRACT

The present invention provides a superconducting block, comprising, a pair of cores with materials that are electrically conductive in their normal states. The pair of cores are embedded in the shell with an intervening centroidal distance, with a material that is electrically conductive in its normal state. The embedded pair of cores and the shell are configured to be superconductive. The present invention also provides a superconducting nanocrystal with at least the superconducting block. The present invention also provides a superconductive device with at least the superconducting block and the superconducting nanocrystal. The present invention further provides a process for fabricating the superconducting block and superconducting crystal. The present invention provides superconductors (superconducting block, superconducting nanocrystals) that can be employed to attain superconductivity at high temperatures, corresponding to temperatures existing in the terrestrial ambient and even higher.

The subject matter of the present invention relates to a superconducting block, superconducting nanocrystal and a superconducting device, which are capable of exhibiting superconductivity under ambient conditions. The present invention further relates a process for the fabrication of the superconducting block and the superconducting nanocrystal.

### BACKGROUND OF THE INVENTION

Nanocrystals (NC structures) are materials which have a particle size of a few nanometers. Properties of the NC structures can be tuned by varying their size and shape. Typically, NC structures are used in optical applications, such as light-emitting devices, diode lasers, photovoltaic and the like. NC structures have also been used for sensing molecular species and enhancing local electric fields.

Whereas, superconductors are materials that do not exhibit resistance to the passage of current. Several ordinary materials turn into superconductors upon cooling below a certain temperature or else by applying a high pressure or both. Several superconductors also expel magnetic fields, and consequently the emergence of superconductivity is typically identified by observing a drop in resistance below transition temperature or else the appearance of strong diamagnetism or both.

Superconductivity has generally been inferred by observing a drop in sample resistance as well as the emergence of strong diamagnetism in materials. Strong characteristic diamagnetism is referred to as the Meissner effect. This occurs because many classes of superconductors are expected to expel magnetic fields from their bulk. Thus, these in an idealized scenario, these are characterized by volume magnetic susceptibilities of −1. In practice, because of impurities, existence of polycrystallinity etc., superconductors do not exhibit perfect diamagnetism, however their response is none the less significantly stronger than ordinary materials. For example, even highly diamagnetic normal materials such as bismuth and pyrolytic carbon have volume susceptibilities of the order of −10⁻⁴. However, certain classes of superconductors do not exhibit strong diamagnetism. Superconducting nanocrystals are known in prior art to show relatively weak diamagnetism due to size effects. Materials such as tantalum exhibit a weak diamagnetic response, due to their peculiar grain structure. In addition, certain superconductors such as p-wave materials are expected to have ferromagnetic superconducting states.

Superconductors are employed for applications where resistance-free or nearly-resistance-free flow of current is desirable. This is the case in most electrical interconnects. In other implementations, superconductors are used to make magnets that are employed to generate fields as large as tens of tesla (T). Such magnets are employed, for instance, to make nuclear magnetic resonance machines for scientific research as well as magnetic resonance imaging systems for medical diagnostics. However, these known superconductor devices undergo transitions at low temperatures and/or elevated pressures. Superconductors are also characterized by the occurrence of a fixed phase. Devices that rely on measurement of small changes in the phase of the superconductor are also known. These are used for example to sense tiny magnetic fields. Further, the existence of a well-defined phase of the superconducting state is being exploited for the making of quantum computers.

Multilayer nanostructures are made using layers of one material embedded into the other. For instance, gold nanorods having a length of about 150 nm and a width of about 20 nm are coated with a silver overlayer having thickness of 1-20 nm.

Cobalt spheroids that are coated with a gold over layer with thickness of 5 nm are also known.

Nanostructures with a growth of silver nanorod 10 nm wide and roughly 100 nm over a gold spheroid are also known in the art.

Nanostructures with embedded clusters of gold with size less 1 nm into a cobalt matrix are also known.

However, these known structures are not known to exhibit superconductivity under ambient temperature and pressure conditions.

NC structures of superconductors such as lead, are known to undergo superconducting transition, under reduced temperature conditions.

It is also known in the art that tiny nanoparticles of metals such as aluminum and tantalum, exhibit elevated transition temperatures that are higher than bulk forms of these materials.

In addition, certain pressurized materials are known to exhibit higher superconducting transition temperature compared to their unpressurized states.

In the superconductors known in the prior art, the transition to the superconducting phase occurs only at extremely low temperatures and/or high pressures. This has limited the practical applications of superconductors to situations of extreme importance where no known alternatives exist (e.g. medical diagnostics). Superconductors that have transition temperatures above room temperature will be the preferred choice for the transport of electricity in power grids. Therefore, there is a need for superconducting devices that can perform under ambient temperature, pressure conditions and without a need for extensive cooling of the devices. Accordingly, there is a need for superconducting materials that undergo the normal-to-superconducting transition at elevated temperatures, preferably at room temperature and above as well as under ambient pressure conditions.

Publications titled viz., (i) Onset of ATC superconductivity in Ag5Pb2O6/CuO composite, (ii) Possible Exciton Mechanism of Superconductivity in Ag₅Pb₂O₆/(CuO—Cu₂O) Composite, (iii) PbCO₃.2PbO+Ag₂O (PACO) systems: route for novel superconductors, (iv) Does Mesophase Ag₄₊ₓPb₂O_{6-z} (0≤x≤1, 0.5≤z≤0.75) Appeal for a Point Contact ATc Superconductivity? by Djurek et. al., have described the emergence of superconductivity in Bystrom-Evers type compounds like Ag₅Pb₂0₆ under special circumstances. These documents disclose superconductivity in composites like Ag₅Pb₂0₀/CuO, Ag doped Pb₂O₃ where the possibility of superconductivity transition at room temperature and above. The composites having a transition temperature of around 350 K and superconducting at 270 K are disclosed. However, these disclosures disclose exciton-polariton models for the deposition of silver at material grain boundaries in the form of clusters, to obtain superconductors. However, these disclosures do not disclose any essential features, which would resolve the problems relating to the configuration of cores and shells, to result in a superconductor, at ambient temperature and under ambient pressure conditions.

### OBJECTS OF THE PRESENT INVENTION

The primary object of the present invention is to provide a superconducting block, with cores that are embedded in a shell that exhibits superconductivity at an ambient temperature and under atmospheric pressure.

An object of the present invention is to provide superconducting nanocrystal with the superconducting block(s) that exhibits superconductivity at an ambient temperature and under atmospheric pressure.

Another object of the present invention is to provide a superconducting device with superconducting nanocrystal and superconducting block(s) that exhibits superconductivity at an ambient temperature and under atmospheric pressure.

It is also an object of the present invention to provide a process for the fabrication of the superconducting block and the superconducting block and nanocrystal.

### SUMMARY OF THE INVENTION

The present invention provides a superconducting block, comprising, a pair of cores with materials that are electrically conductive in their normal states. The pair of cores are embedded in the shell with an intervening centroidal distance, with a material that is electrically conductive in its normal state. The embedded pair of cores and the shell are configured to be superconductive. The present invention also provides a superconducting nanocrystal with at least the superconducting block. The present invention also provides a superconductive device with at least the superconducting block and the superconducting nanocrystal. The present invention further provides a process for fabricating the superconducting block and superconducting crystal. Accordingly, the present invention provides a unique nano-architecture that relies on a configuration of the cores that are embedded in the shells to exhibit superconductivity. This will enable devices to be prepared out of superconductors that can function in the ambient as well as at elevated temperatures.

### BRIEF DESCRIPTION OF DRAWINGS

FIG. 1(a) is a schematic illustration of the superconducting block of the present invention, with a pair of cores that are embedded in a shell.

FIG. 1(b) is a schematic illustration of the superconducting block of the present invention, with a pair of cores with multiple layers that are embedded in a shell.

FIG. 1(c) is a schematic illustration is a schematic illustration of the superconducting block of the present invention, where a plurality of cores are with different materials.

FIG. 2(a) is a schematic illustration of a superconducting nanocrystal of the present invention, depicting a plurality of superconducting blocks that are integrally connected to one another.

FIG. 2(b) is a schematic illustration of an arrangement of a plurality of non-integrated superconducting nanocrystals, with mesoscopic regions.

FIG. 3(a) is an X-ray Powder Diffraction (XRD) pattern illustrating structural characteristics of the exemplary superconducting nanocrystal with silver (Ag) cores that are embedded in the shell of gold (Au).

FIG. 3(b-c) are scanning transmission electron microscopy (STEM) images of the exemplary superconducting nanocrystal with silver (Ag) cores that are embedded in the shell of gold (Au).

FIG. 3(d-h) depicts High Resolution Transmission Electron Microscopy (HRTEM) images of exemplary superconducting nanocrystal with the cores of silver (Ag) that are embedded in the shell of gold (Au).

FIG. 4(a) is a TEM image of exemplary superconducting nanocrystal of the present invention.

FIGS. 4(b-c) are TEM images of exemplary superconducting nanocrystal of the present invention with various degrees of aggregation of cores in a shell.

FIGS. 4(d-g) are TEM images of agglomerated cores in the shell of the superconducting nanocrystal of present invention.

FIG. 5(a-h) are high angle annular dark field (HAADF) images with elemental mapping of superconducting nanocrystal of the present invention, showing the formation of silver in patches over gold.

FIG. 5(i) is a transmission electron microscopy (TEM) and scanning transmission electron microscope (STEM) image of the exemplary superconducting nanocrystal.

FIG. 5(j) depicts HR-TEM images of the exemplary superconducting nanocrystal of the present invention.

FIG. 5(k) depicts HR-TEM and STEM images of the exemplary s superconducting nanocrystal.

FIG. 5(l) depicts High-Angle Annular Dark-Field-STEM (HAADF-STEM) images of exemplary superconducting nanocrystal.

FIG. 5(m) depicts high-angle annular dark-field-stem (HAADF) images with elemental mapping of the exemplary superconducting nanocrystal.

FIG. 5(n) depicts high-angle annular dark-field-stem (HAADF) images with elemental mapping of superconducting nanocrystal with size of silver core is about 1 nm.

FIG. 5(o) shows high-angle annular dark-field-stem (HAADF) images with elemental mapping of the exemplary superconducting nanocrystal.

FIG. 5(p) depicts high-angle annular dark-field-stem (HAADF) images with elemental mapping of the exemplary superconducting nanocrystal.

FIGS. 6(a-d) are the extinction spectra of silver and gold nanospheres (6(a)) and superconducting nanocrystal structure of the present invention (6(b-d)). FIG. 6(e) is an energy dispersive X-Ray spectrum exhibiting elemental composition of the exemplary superconducting nanocrystals of the present invention. FIGS. 6(f) and (g) depict elemental distributions (along the red line) show that superconducting particles that are composed of ˜1 nm silver cores embedded within a gold matrix.

FIGS. 7(a-e) are the extinction and scattering spectra of superconducting nanocrystal structure of the present invention (7(a-c)) as well as the extinction and scattering spectra of gold NC structures (7(d)) and quantum dot (QD) (7(e)). FIGS. (7aa, 6bb and 6cc) show an expanded y axis to enable observation of the extinction.

FIG. 8 is a graphical depiction of the growth of gold on superconducting nanocrystal structure of the present invention.

FIG. 9(a-c) depict an appropriate growth of gold on superconducting nanocrystal structure of the present invention for obtaining the NC structure with transition temperatures at 323 K, 234 K and 150 K and at zero magnetic fields.

FIG. 10 depicts the resistance of the exemplary superconducting nanocrystal structure of the present invention with a transition temperature of 237 K.

FIG. 11 depicts the effect of magnetic field on the superconducting transition temperatures.

FIG. 12 depicts the effect of applied current on the superconducting transition temperatures.

FIGS. 13(a-b) depict the resistivity of 20 nm gold film and the superconducting nanocrystal structure. FIGS. 13(c-d) depict the resistivity of the superconducting nanocrystal deposited on a 25 nm silver film as well as the resistivity of the silver film itself.

FIG. 14 depicts the diamagnetism of the exemplary superconducting nanocrystal structure with a transition temperature well above room temperature.

FIG. 15(a-c) depict the effect of gold growth on superconducting nanocrystal structures.

FIG. 16(a) depicts the effect of strength of externally applied magnetic field on the exemplary superconducting transition temperatures and diamagnetism. FIG. 16(b) shows the properties of bulk lead that is a superconductor known in prior art. FIG. 16(c) depicts the formation of silver core formation at different times. FIG. 16(d) depicts volume susceptibility of superconducting nanocrystals with transition temperature at 310 K.

FIG. 17(a) is a schematic illustration of a superconducting device of the present invention with the superconducting nanocrystal.

FIG. 17(b) is a schematic illustration of the superconducting device that is arranged on a substrate, along with means for extracting or inducing power and the superconducting nanocrystal.

FIG. 18(a-b) is a schematic view of and the corresponding photograph of a device with a superconducting film of the present invention.

FIG. 19 is a schematic of a device that relies on phase differences between different superconductors.

FIG. 20(a-c) show the optical properties of superconducting Pt—Cu, Mn—Cu, Pd—Cu NCs.

FIG. 20(d-e) show the TEM images of Mn—Cu and Au—Cu superconducting NCs.

FIG. 20(f) shows the optical properties of Au—Ag/Ag NCs.

FIG. 20(g) shows the optical properties of rod-shaped Au—Ag NCs.

FIGS. 20(h-j) exemplify optical data of various nanocrystals.

FIG. 21 is a flow drawing illustrating process steps in accordance with one aspect of the present invention.

FIG. 22 is a flow drawing illustrating process steps in accordance with another aspect of the present invention.

FIG. 23 is a flow drawing illustrating process steps in accordance with yet another aspect of the present invention.

FIG. 24 is a flow drawing illustrating process steps in accordance with yet another aspect of the present invention.

FIG. 25 is a flow drawing illustrating process steps in accordance with yet another aspect of the present invention.

### DETAILED DESCRIPTION OF THE INVENTION

This invention concerns the construction of superconductors where the superconductivity arises as a consequence of specific nanoscale architectures. In the most general interpretation, the superconductors described in this invention comprise building blocks that are referred to as superconducting blocks. Each superconducting block comprises of at least a pair of cores embedded into at least a shell. Each building block is capable of exhibiting superconductivity in isolation or in proximity to other building blocks or in proximity to other materials. It is however possible that certain aspects of superconductivity of a superconducting block may change depending upon its proximity to other superconducting blocks. For example, the temperature at which such a block transitions into a superconducting state may be altered by proximity to other superconducting blocks or materials. A superconducting block may be visualized as a single superconducting nanoparticle that comprises at least a pair of cores in at least a shell. Alternatively, it is feasible to advantageously create a superconducting nanocrystal out of a plurality of superconducting blocks. It is further possible to construct a macroscopic superconductor from superconducting building blocks. Chemical or thermal treatment of such architectures may lead to the disappearance of distinct boundaries between distinct building blocks, leading to the emergence of a superconductor that comprises of at least a pair of cores and at least a shell. In a bulk superconductor the entire material is characterized by a single macroscopic parameter called the phase. The phase is not affected by structural defects or structural grain boundaries within the superconducting material. The above definition of the superconductive block is thus consistent with the region of superconductor that has a phase. This definition is thus also distinct from structural features such as granularity or nanocrystals that constitute a superconductor.

Accordingly, the present invention provides a superconducting block, a superconducting nanocrystal with the superconducting blocks and a superconducting device with the superconducting crystal, which are capable of exhibiting superconductivity at an ambient temperature and under atmospheric pressure.

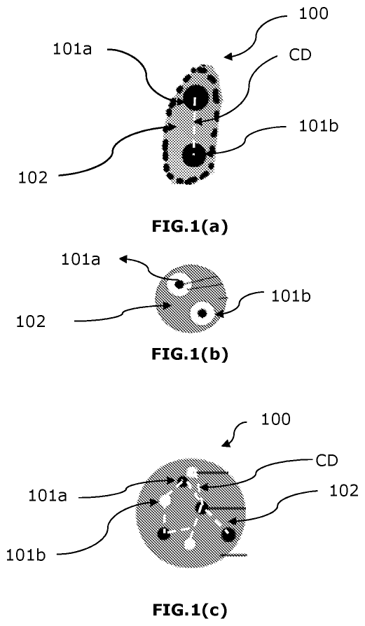

Initially, the preferred embodiments pertaining to the superconducting block are described by referring to FIG. 1(a). The superconducting block of the present invention, as illustrated in FIG. 1(a), is provided with a basic fundamental unit, comprising a pair of cores 101a and 101b, which are embedded or encapsulated in a shell 102. The pair of cores 101a, 101b are made of materials that are electrically conductive in their normal states. The pair of cores 101a, 101b are embedded in the shell 102, with an intervening centroidal distance (CD) between the cores 101a, 101b. The embedded pair of cores (101a, 101b) and the shell (102) exhibit superconductivity, even though the materials of the pair of cores and the shell do not exhibit superconductivity in their normal states.

In this preferred embodiment each of the cores 101a and 101b, which is embedded in the shell 102, is preferably provided with a diameter in the range of 0.3 to 2.7 nanometers. The selection of the preferred core diameter, influences the efficacy of charge transfer between the cores 101a and 101b and the surrounding shell 102. Here, the efficacy is considered in terms of a total charge that is transferred to the total core and shell volume. Therefore, depending on the choice of the core and shell material, the charge transfer is optimized for cores of intermediate size. In case of very large-sized cores, the efficacy of charge transfer at the core-shell interface is suppressed due to the reduced surface to volume ratio. Whereas, in respect of the very small-sized cores, even though the surface to volume ratio is large, coulomb charging of the core material reduces the efficacy of the transfer. It is therefore, it is not only advantageous but also essential to select cores with optimal core diameters, to achieve the efficacy of charge transfer between the cores 101a and 101b and the surrounding shell 102.

The cores 101a and 101b are disposed with the intervening centroidal distance (CD) of 0.7 to 20 nanometers (nm). The centroidal distance of the cores 101a and 101b is related to the density of the cores 101a and 101b in the shell 102. The average inter core centroidal distance thus determines the total extent of charge transfer occurring per unit volume of the superconducting block 100. This factor plays a crucial role in determining the density of low energy modes of the electrons and therefore the superconducting properties of the superconducting block 100. As shown in the present invention, signatures of large scale changes to the conduction electrons in the superconducting block 100 can only arise, when more than one core is present in the superconducting block 100. Accordingly, superconductivity in the superconducting block 100 is achieved by embedding at least a pair of cores 101a and 101b in the shell 102.

Therefore, the superconducting block 100 of the present invention is a nanostructure with at least a pair of cores 101a and 101b that is made of first material that is electrically conductive in its normal state, along with the shell that is made of a second material, which is also electrically conductive in its normal state. Accordingly, the first and second materials of the superconducting nanocrystal structure are selected from a group of materials that advantageously exhibit dissimilar work functions, volta potentials or electrochemical work-functions. The existence of differences in volta potentials and other descriptors of Fermi level position of the constituents is an important property of the choice of core and shell materials. This difference signifies a potential gradient between the two constituents that gives rise to a local charge transfer between the core and shell layers. Accordingly, in the present invention, the regulation of local restructuring of the electron distribution in the superconducting block 100, renders superconductivity to the hitherto conductive materials in their normal conditions. In other words, superconductivity that is achieved in the superconducting block 100 is based on the occurrence of high efficacy charge transfer between at least two constituent conductors in a nanoscale. The charge transfer depends on the volta potential differences between the two materials, and is not greatly influenced by other details of the materials such as their lattice structure and vibronic modes. The charge transfer is thus robust to the details associated with the two conductors, and only relies upon the presence of conducting/free or mobile electrons in the desired materials along with an intrinsic volta potential difference.

Since, the superconducting block (100) of the present invention relies on the occurrence of high efficacy charge transfer between at least two constituent conductors in the nanoscale. The primary guiding factor in selecting the two materials for the cores and the shell is that there exists a volta potential difference between these two materials, which is sufficient to ensure adequate charge transfer between the core and shell. The selection of two materials for core and the shell is made based on the magnitude of volta potential difference that is sufficient to ensure an adequate charge transfer between the material of the core and shell.

Accordingly, the material for the shell can be preferably selected from the same material as that of the material that is used for the cores 101a and 101b, as long as the magnitude of volta potential difference between the materials for the cores and the shell is greater than or equal to ≥0.4V. It is also understood here that higher magnitudes of volta potential difference may also lead to an improved charge transfer. Therefore, the upper limit for the preferred range of magnitude of volta potential can be suitably selected, based on the selection of the materials.

Thus the preferred materials (first and second materials) for the cores and the shells are selected from alkali metals, alkaline earth metals, transitional metals, post transitional metals, metalloids and lanthanoids, preferably Lithium (Li) Sodium (Na), Potassium (K), Caesium (Cs), Magnesium (Mg), Beryllium (Be), Calcium (Ca), Strontium (Sr), Barium (Ba), Gold (Au), Copper (Cu), Nickel (Ni), Molybdenum (Mo), strontium (Sr), silver (Ag), Cobalt (Co), Iron (Fe), Niobium (Nb), Zinc (Zn), Tungsten (W), Platinum (Pt), Palladium (Pd), Titanium (Ti), Chromium (Cr), Scandium (Sc), Manganese (Mn), Vanadium (V), Zirconium (Zr), Hafnium (Hf), Cadmium (Cd), Aluminum (AI), Gallium (Ga), Indium (In), Tin (Sn), Lead (Pb), Neodymium (Nd), Tellurium (Te) Antimony (Sb) Bismuth (Bi) or alloys and compounds thereof.

It is also within purview of this invention to use materials that non-elementary conductors, preferably oxides of metals, doped semiconductors, semi-metals, preferably mercury telluride. It is therefore, further understood here that the materials for the cores and the shell can be selected from materials, which exhibit free or conducting electrons.

In the exemplary aspect of the present invention, the composition of the desired materials of the 101a and 101b and the shell 102 are equally abundant in the superconducting block (100). Whereas, the preferred composition of the desired materials can be unequal and relative to each other.

In the in the superconducting block (100) of the present invention, neither the first nor the second selected material is required to undergo a superconducting transition in isolation, since, superconductivity has never been observed in such materials, for instance gold (Au) and silver (Ag), at any known temperatures and in their normal states.

The relative compositions of the materials, enable to obtain the superconducting block (100), where the transition to its superconducting state occurs at different temperatures. Further, it is also possible that temperatures at room temperature and above for the superconducting transition may be achieved. The transition to its superconducting state is also achieved under atmospheric pressure conditions.

In yet another exemplary aspect of the present invention the molar ratios of the materials that are preferred for the cores 101a and 101b and the shell 102 are in the range of 1:20 to 20:1.

The superconducting block (100), by virtue of having the pair of cores (101a, 101b) that are embedded in the shell (102), with an intervening centroidal distance (CD), the embedded pair of cores (101a, 101b) and the shell (102) exhibit superconductivity. Therefore, a superconductive matrix is formed by the superconducting block (100), where the charge is transferred between the core and shell, resulting in a restructuring of electrons in the two conductors (cores and shell). The resultant restructured electrons in the superconducting block (100), exhibit superconductivity, as long as an adequate density of low energy modes is available within the system. The presence of a density of low energy modes ensures the emergence of a net electron-electron attraction. This attractive interaction between electrons leads to the formation of a Cooper pair, under favourable conditions and the ultimate emergence of superconductivity.

Accordingly, the superconducting block (100), where the cores 101a and 101b, which are embedded in the shell 102, can be configured to exhibit the superconductivity transition, at an ambient temperature and under ambient pressure. The transition to superconductivity can also be achieved at a temperature in the range of 1 mK to 10₄ K and at applied pressure in the range of 0-10¹¹ Pa.

The superconducting block (100), of the present invention can also be configured to exhibit a superconducting state at a wider range of applied temperatures and under pressures, including the ambient. A significant advantageous aspect of the present invention is that it is not necessary to apply a high external pressure in order to attain a superconducting state at high temperatures such as temperatures above 200 K. It is also within the purview of this invention to achieve the superconducting state, at temperatures higher than 298 K and under pressures that are close to 1 atmosphere.

Superconductivity of the superconducting block (100) of the present invention is not affected by lowering of pressures below this value, since this introduces no perceptible structural or electronic transformations into the materials that are employed to create the superconducting block (100). The accessibility of the superconducting state at temperatures as high as and above room temperature even under ambient pressure conditions is one of the principal advantages of this invention, and may be used to make superconducting devices that retain functionality in the terrestrial environments. In addition to the preferred temperature parameter, superconductivity of the superconducting block (100) is obtained under ambient pressure conditions in the range of 0-10¹¹ Pa. It is however, understood by a person of ordinary skill in the art that that the upper limit of the transition temperature is not completely measurable but determined from the magnitude of the superconducting gap between the materials.

The configuration of the superconducting block (100) as shown in FIG. 1(a), is substantially a nanospheroid. The superconducting block (100) of the present invention can be obtained is various configurations such as nanosphere, nanowire, nanotube, nanocube, nanoplate, nanoplatelet and a nanorod.

In yet another aspect of the present invention, as illustrated in FIG. 1(b), the superconducting block (100), which is exemplarily shown as nanosphere, is provided with a pair of cores (101a, 101b) and the shell (102), which are multi-layered. The existence of multi layered core and shell architectures does not add novel mechanistic advantages, however this may be an outcome of the preparation methods adopted to make these materials. Additionally, this may be adopted to fine tune specific aspects of the invention. For example the incorporation of specific materials may lead to a superconductor with lower mass density. Such a material may be useful for applications under challenging conditions.

In yet another exemplary aspect of the present invention, as illustrated in FIG. 1(c), the superconducting block (100) is provided with a plurality of cores (101a, 101b) that are embedded in the shell (102) with centroidal distances (CD). In this exemplary aspect, the materials for the plurality of cores (101a, 101b) are identical or non-identical. The black and white representations as shown in FIG. 1(c) of the cores denote usage of materials of different types for the cores. The existence of a plurality cores comprising different materials does not add novel mechanistic advantages, however this may be advantageous as a preparation method or may be adopted to fine tune specific aspects of the invention. For example the incorporation of specific materials may lead to a superconductor with lower mass density. Such a material may be useful for applications under challenging conditions.

Therefore, the superconducting block (100), of the present invention is fabricated with the pair of cores (101a, 101b) that are separated with an intervening centroidal distance (CD). The materials for the pair of cores (101a, 101b) are electrically conductive in their normal states. The pair of cores (101a, 101b) are embedded or encapsulated in the shell (102) to exhibit superconductivity at ambient temperatures and under ambient pressure conditions.

Hitherto, the preferred embodiments of the superconducting block (100) with at least a pair of cores 101a and 101b that are embedded in the shell 102, are described.

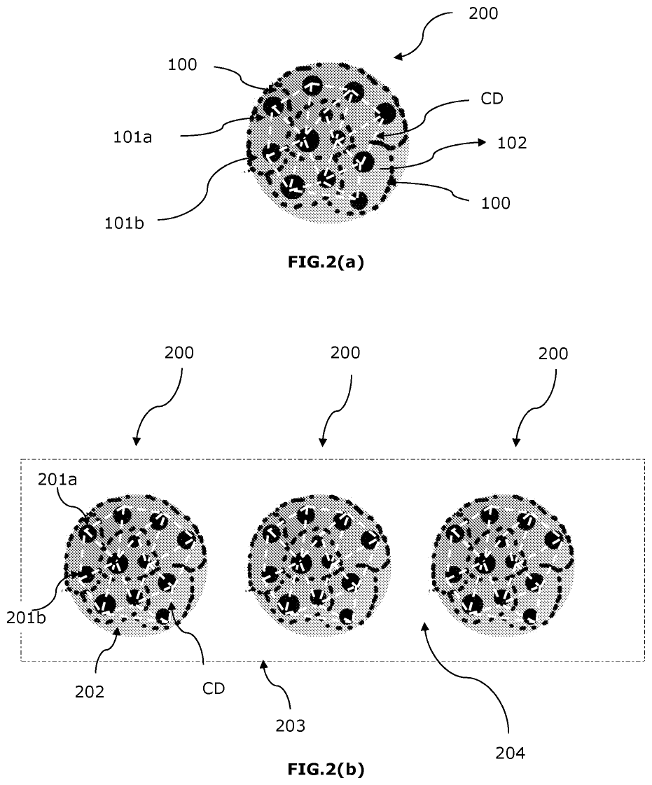

Now, in yet another aspect of the present invention, the preferred embodiments pertaining to a superconducting nanocrystal (200) of the present invention, incorporating a plurality of superconducting blocks (100) are now described, by particularly referring to as shown in FIG. 2(a). The superconducting nanocrystal (200) comprises the plurality of superconducting blocks (100) that are integrally connected to one another, wherein each of the plurality of superconducting blocks (100) include a pair of cores (101a, 101b) with materials that are electrically conductive in their normal states. The pair of cores (101a, 101b) are embedded in the shell (102), with an intervening centroidal distance (CD), where the embedded pair of cores (101a, 101b) and the shell (102) are configured to be superconductive. The plurality of cores (101a, 101b) are disposed in the shell (102), which are electrically conductive in their normal state, with centroidal distances between the cores (101a, 101b) are in the range of 0.7 to 20 nanometers and are configured to form superconductive matrices.

In yet another exemplary aspect of the present invention, the superconducting nanocrystal (200) where magnetic volume susceptibility of the plurality of the superconducting building blocks (100) is less than −0.001 (SI units).

The use of a plurality of cores as opposed to a single core material, is advantageous in applications where the composition of the superconducting nanocrystal (200) is required to be constrained in a certain manner. For instance, in terms of limiting its mass density to make it suitable for a specific target application. In this implementation, a low density superconducting nanocrystal (200) is potentially more advantageous for use in challenging environments. Therefore, the superconducting nanocrystal (200) of the present invention can be aggregated or combined to enable fabrication of mesoscopic and macroscopic superconducting nanocrystal (200).

Now, the preferred embodiments of the arrangement of the superconducting nanocrystals (200) are described by referring to FIG. 2(b). In this exemplary aspect, the plurality of the superconducting nanocrystals (200) are disposed in a medium (203) and where the plurality of the superconducting nanocrystals (200) are not integral to one another and are separated by regions (204) of conductor. This enables the creation of a composite material, where the superconductive regions (204) are distributed within the conductor. It is further possible for superconductivity to be induced into the conductor through proximity effects, leading to low resistivity.

The resistivity of the materials that are used to form superconducting nanocrystals along with the medium (203) that are disposed in a conductor (200), is preferably less than 1×10⁻⁹ Ohm-m. The resistivity as shown here pertains to the exemplary superconducting nanocrystals that are made of materials such as gold and silver and the medium (203), which is silver. It is therefore, understood here that superconducting nanocrystals can be disposed in a preferred medium, in the manner as disclosed herein along with other suitable materials and media.

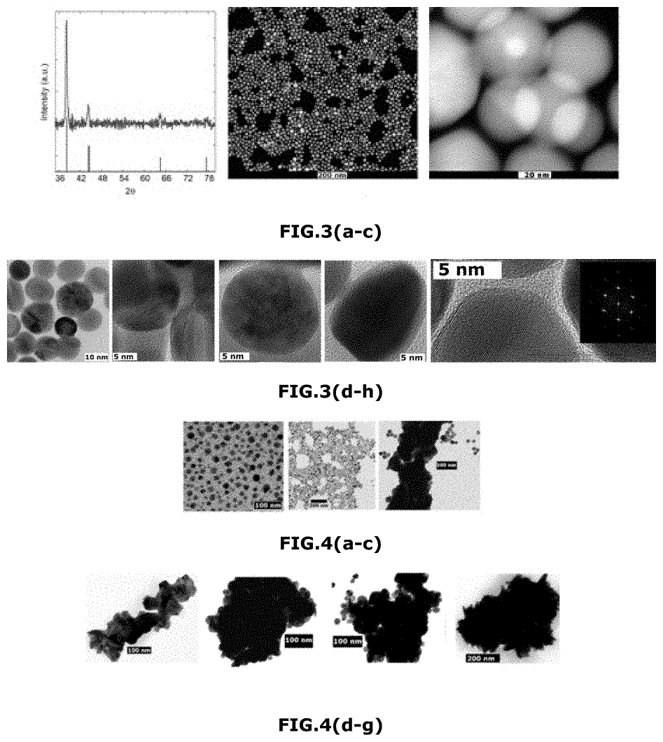

The preferred embodiments of the exemplary superconducting nanocrystal with cores that are made of silver (Ag) material where the cores are embedded in a shell made of gold (Au) are Now by referring to FIG. 3(a), which is an XRD pattern of an exemplary superconductor of the present invention that is made of plurality of silver (Ag) cores, which are embedded in the shell of gold (Au) is described. FIG. 3(a) is where standard pattern of gold is shown below the nanostructure data. As evident from this figure, it is clear that the superconducting nanocrystal has a lattice constant that is identical to its constituent materials gold and silver.

Whereas, FIGS. 3(b-c), which are STEM images of exemplary superconducting nanocrystal, where a superconducting matrix of nanocrystals (NCs) is shown. These images depict a consistent presence of silver cores (about 1 nm in diameter) within the shell that is made of gold material.

The dark-field scanning transmission electron microscopy (STEM) image of these superconducting nanocrystals depict a homogeneity as shown in FIG. 3(b). This technique allows for the observation of element-specific contrasts in electron scattering fashion and further allows these to be compared qualitatively. This particular exemplary data thus establishes the existence of a homogenous ensemble of nanoparticles that are made of a plurality of superconducting blocks. Nanoparticles are qualitatively similar to each other in terms of their electron diffraction contrast, shape and as well as the size. Further, the chemical treatment employed in the invention leads to sintering between particles, which is shown FIG. 3(c).

The exemplary superconducting nanocrystal structure is provided with cores of silver (Ag) metal embedded into the shell of gold (Au), where the grain size or the diameter of the core that is made silver (Ag) material, is in the range of about 0.3 to 1.8 nm and the magnitude of the volta potential difference between materials of cores and the shell is at least 0.4V. The volta potential difference determines the efficacy of charge transfer between the core and the shell.

The microstructure of the superconducting nanocrystal structure is as shown in FIG. 3(d)-(h), as TEM images.

FIGS. 4(a-c) are TEM images of exemplary superconducting nanocrystal of the present invention with various degrees of aggregation of cores in a shell. This has been obtained by removal of ligands surrounding the nanocrystals leading to their agglomeration.

FIGS. 4(d-g) are TEM images of agglomerated cores in the shell of the superconducting nanocrystal of present invention. This has been obtained by removal of ligands surrounding the nanocrystals leading to their agglomeration. This further exemplifies the variable morphologies of the nanoparticles of super conductors. In particular these may be formed into spheres, spheroids elongated rod like particles or irregular shapes.

The superconductor with superconducting nanocrystal structures may be aggregated to form larger structures, as exemplarily shown in FIGS. 4(d-g).

Further, the properties of these superconducting NC structures are also shown in TEM images. In particular, while FIG. 4(a) and FIG. 4(b) show individual particles and whereas FIG. 4(c) shows the appearance of sintered structures that are formed due to the ligand replacement step, which is used in the process steps of the present invention as hereinafter described. FIG. 4(c-g) also clearly indicate agglomeration of the superconducting NC structures, which is preferred for good electrical and magnetic measurement. Agglomerated superconducting nanocrystal structures indicate connectivity between various superconducting particles. This enables electrons to travel unimpeded from one region of the agglomerate to another, provided there is direct contact between the nanocrystal surfaces. Further, the absence of voids between the nanocrystals of superconductors is also important for diamagnetic susceptibility of these materials. Since most common superconductors are diamagnetic, magnetic lines of force are expelled from the bulk of such materials. If the superconductor is nanostructured, it is nonetheless possible for magnetic lines of force to bend around individual particles and permeate through the voids of such materials.

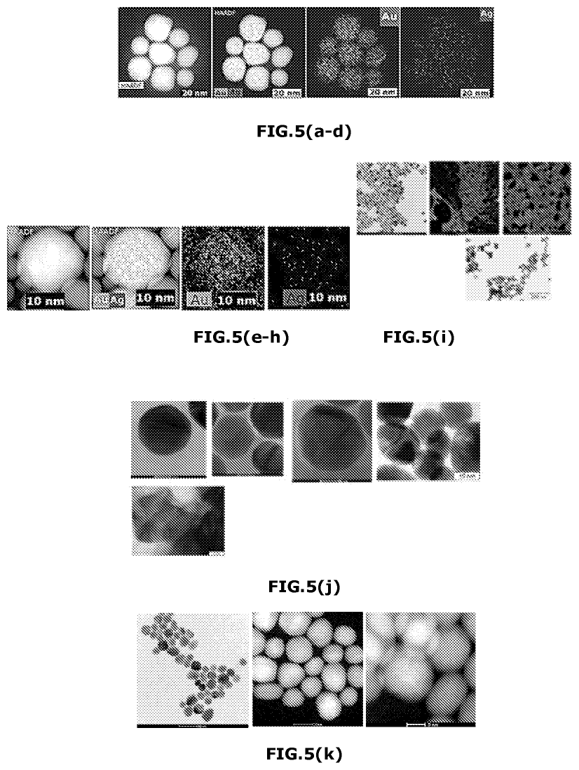

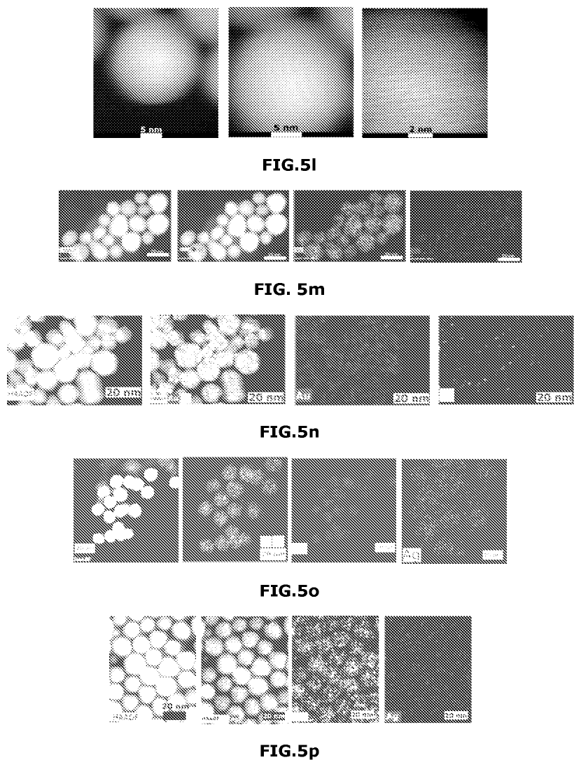

FIG. 5(a) shows the existence of structurally inhomogeneous dark and bright regions within each particle.

As shown in FIG. 5(b), FIG. 5(c) and FIG. 5(d), these correspond to small (0.3-2.7 nm) silver particles embedded into a matrix of gold. The physical characteristics such as size and the structure of the exemplary superconductor that is made cores of Ag and the shell of Au now particularly described by referring to FIGS. 5 (e-h). These figures show the elemental distributions of Ag and Au within each nanoparticle. From these figures it is evident that each nanoparticle comprises one or more superconducting building blocks. Ag is formed into cores roughly 1 nm in size while Au constitutes a shell into which these cores are embedded. In these examples it is evident that an average inter core centroid separation of 5-7 nm is maintained for these nanoparticles.

FIG. 5(a-p) depict the distributions of Ag cores within Au shells. These figures also confirm the presence of at least one superconducting building block within each of the imaged nanoparticles. The densities of cores per unit volume of the nanoparticles are estimated to correspond to centroidal distances between 4-8 nm in each of the nanoparticles. High-Angle Annular Dark-Field (HAADF) images with elemental mapping of the exemplary superconducting nanocrystals of the present invention thus show that the size of the silver core is in the range of about 0.3-2.7 nm. Collectively, these figures imply the formation of a particle that comprises of 0.3-2.7 nm silver nanocrystals embedded into a gold matrix. Therefore, the superconducting nanocrystal of the present invention is a superconducting block comprising at least two materials, with the magnitude of volta potential difference of more than 0.4 V, where one of materials is organized into nanocrystals and are distributed into a matrix of the other material.

Now, the characterization details of the exemplary superconducting nanocrystal (Ag—Au nanocrystals) of the present invention are provided. The exemplary superconductor is characterized, by X-ray Powder Diffraction (XRD) and transmission electron microscopy (TEM) by dissolving cleaned NC structure in water, and then drop casting on a glass substrate. A 0.15406 nm X-ray, Cu-Kα source is used to collect all data. TEM grid is prepared with ultra clean sample in water solution. HR-TEM images are obtained on a Themis TITAN transmission electron microscope (200 kV). STEM is performed in a Themis TITAN TEM operating at 200 kV. STEM-EDX elemental mapping is also performed using the same instrument. The obtained fine grains are separated from reducing solution, dried and pellet is made by pressing on a titanium die. The obtained pellet typically weighing about 65-120 mg is subjected to magnetometry measurement. The magnetometry measurement is done in a SQUID, MPMS®3 from Quantum Design. The sample is then filled on a tube and is attached to the sample holder. The holder is placed on SQUID and various measurements are taken.

For the measurement of resistivity a film is prepared in the following manner. A partially cleaned sample is drop casted on a glass substrate having four gold metallic pads (100 nm high each with an equidistant separation of 1 mm) deposited on it. The cross linking is done by adding CHCl₃ followed by KOH (aqueous). The process of addition of CHCl₃ is followed by KOH (aqueous) and this process repeated twice. The film is dried in vacuum inside a desiccator and moved to a high pressure nitrogen Glove-box immediately after drying. Nitrogen gas is passed over the film prior to the measurement. The measurement is carried out in PPMS6000 from quantum design and four probe measurement setup from Agilent Technologies.

Consistent with their composition, Au—Ag NC structures when cast into films show powder X-ray diffraction (XRD) patterns that are obtained are similar to ordinary patterns of Au and Ag, as shown in FIG. 3(a).

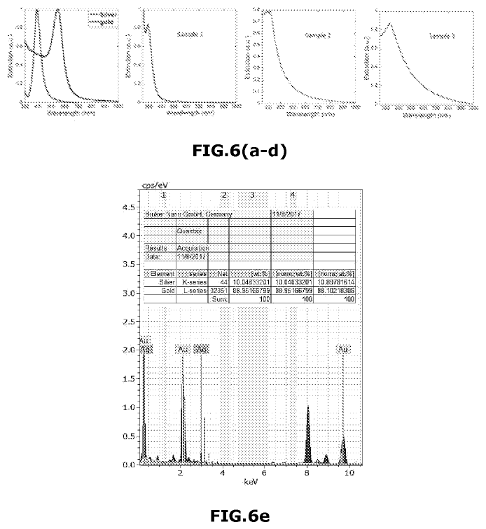

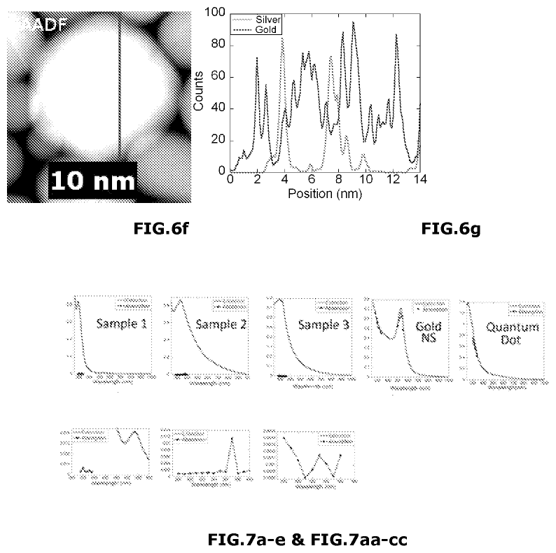

The optical extinction spectra of the exemplary superconducting nanocrystal are exemplified in FIGS. 6(a-d). FIG. 6(a) depicts the typical extinction for ordinary gold and silver particles. FIG. 6(b), FIG. 6(c) and FIG. 6(d) depict the optical extinction of three different superconducting nanocrystal of Au—Ag. In each case, the extinction feature is analogous to the localized surface plasmon resonance is far-removed and blue shifted from the normal extinction maximae of gold and silver. Indeed, the maximum is further blue-shifted even compared to the silver extinction maximum. As the extinction maximum in such plasmonic particles is linked to the relative energetic position of interband transitions, this observation imply restructuring of the electron gas in these nanocrystals into a form that exhibits modes at energies higher as well as lower than the surface plasmon resonance energy of gold and silver. In general, it is possible to create optically active plasmonic modes lower than the surface plasmon energies of any material through a straightforward regulation of its shape. For example, elongated nanorod shaped particles exhibit a longitudinal plasmon resonance that occurs at energies dependent on the particle length to width aspect ratio. In the optical extinction spectra of these particles, this longitudinal plasmon resonance is located at energies lower than the surface plasmon resonance. These behaviors of plasmonic systems are adequately described by considering the bulk dielectric functions of constituent materials of these nanoparticles. The effects of shape are then described by theories such as Mie theory, that are well known in the prior art. Resonances higher in energy than the surface plasmon resonance cannot be accounted for by theoretical explanations that assume constant dielectric functions of the particles. The existence of higher energy (shorter wavelength) resonances compared to surface plasmon resonances thus implies restructuring of the electron gas which is also consistent with the other properties of these particles. It is further evident that partitioning of the extinction of these particles into scattering and absorption components provides a direct evidence of reduced dissipation in these NC structures. The extinction of this material is characterized by dissolving NC samples in water. An integrating sphere coupled to an FLS920 spectrometer (Edinburgh Instruments) was employed. The dispersion was illuminated with light at various wavelengths derived from a xenon lamp, and the light output from the integrating sphere was detected using an R928 PMT coupled to an output spectrograph. The ratio light collected in presence of the sample was compared to the amount of light received when a cuvette of neat solvent was placed in the sphere. This enables us to directly measure the absorbance. The extinction is determined using a simple absorption spectrometer. Scattering is inferred as the difference of extinction and absorption. For purposes of comparison, the same methods are adopted for a purely absorptive material (semiconductor nanocrystals) and ordinary metal nanoparticles (gold). The measurable absence of optical absorption in these particles along with the energetics of the observed resonance entirely confirm the restructuring of the electron gas in these nanocrystals and the emergence of new modes. The existence of a tail of states (as evidenced in FIG. 6c, 6d) that extends to lower energies shows that the new modes created within the electron gas may be tuned to an energy relevant for inducing electron pairing that is necessary for superconductivity.

In conventional superconductors, electron pairing most generally occurs due to phonons or lattice vibrations that mediate electron-electron attraction. Electron attraction is itself a prerequisite for the attainment of a superconducting state. In the case of the present invention, this attraction is mediated through the emergence of new modes as is exemplified above.

The extinction spectra of gold nanosphere and superconducting NC structures as depicted by FIGS. 6(a-d), demonstrate analogs of a Plasmon Resonance position that is not expected using available dielectric functions of gold and silver and using a standard treatment such as Mie theory or variants thereof in the case of superconducting nanocrystals. In contrast, the extinction spectra are in the appropriate positions in the case of gold and silver nanospheres.

FIG. 6 also exemplifies the differences between the optical extinction of silver and gold NCs (FIG. 6(a)) and superconducting NCs (FIG. 6(b-d)).

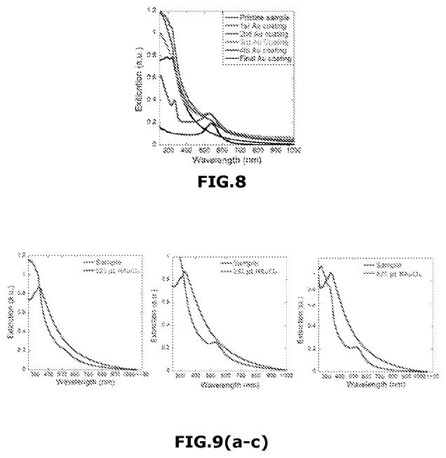

Effects of additional Au shell growth on superconducting nanoparticles are illustrated in FIG. 8 that exemplifies over coating. Further, this is highlighted in FIG. 9(a-c) that describe different optical properties in differently coated superconducting nanocrystals. Finally this is highlighted in FIG. 15(a-c) that show different transition temperatures in the superconducting nanocrystals as observed in FIG. 9. This consistently establishes that optical properties may be employed to estimate the transition temperatures of this class of superconducting materials and that transitions in resistivity are ultimately correlated to the optical spectra. Further, it is inferred that over coating may be employed as a convenient tool to regulate the transition temperatures and superconducting gaps of the class of NCs described in the present invention.

FIG. 6(e) depicts energy dispersive X-Ray spectrum and elemental composition of the exemplary superconducting nanocrystals, demonstrating the elemental composition of Au/Ag superconducting NCs. FIGS. 6(f) and (g) depict elemental distributions (along the red line) of the superconducting particles are of the present inventions that are composed of ˜1 nm silver cores embedded within a gold matrix. In particular, the elemental distribution of Au—Ag superconducting NCs are shown. The concentrations of silver and gold are shown as a function of position along the slice shown, which confirms the presence of small cores. This figure thus further establishes that the general motif of 0.3-2 nm sized nanocrystals embedded in a matrix of a second metal is present in superconducting nanocrystals described in the present invention.

The superconducting nanocrystal structure is also configured to demonstrate a significantly reduced dissipation, even at optical excitation frequencies. This manifests itself as a significant enhancement in scattering of light with little actual light absorption by particles. The wavelength at which enhanced elastic light scattering is observed is dependent on the particle shape and state of aggregation, which is exemplarily shown in FIGS. 7(a-e). FIGS. 7(a-c) show the absence of light absorption in superconducting nanocrystals. At the same time, ordinary gold nanocrystals as well as semiconductor quantum dots (FIG. 7(d-e)) show significant absorption and negligible scattering.

FIG. 7(a-e) are the extinction and absorption spectra of the superconducting NC structures of the present invention (Gold NC structures and Quantum Dot (QD) are also shown). Extinction spectra of the superconducting NC structures show absorption negligible compared to Gold NS and Quantum Dot. FIGS. 7(aa-cc) depict the absorption contribution towards extinction for the superconducting NC structures. It is also observed that as presented in FIGS. 7(a-c) and FIG. 7(aa), FIG. 7(bb) and FIG. 7(cc), the superconducting NC structures can be engineered to show large scattering and negligible optical absorption at the extinction maximum. Other materials including semiconducting NC structures as well as plasmonic gold NC structures exhibit significant losses and consequently show high values of optical absorption in regions where extinction is large. The existence of a very large scattering and negligible absorption in small particles is consistent with the existence of a very large (few eV) superconducting gap.

FIG. 8 demonstrates the effect of growing gold layer on top of the superconducting nanocrystal structure that reduces the transition temperature. Progressive metal coating on superconducting NC structures leads to the gradual deterioration of their optical properties and their eventual conversion into optically ordinary NC structures. This is exemplified in FIG. 8 that depicts the gradual emergence of a gold Plasmon in these NC structures as gold is over coated on this material. The eventual NC formed after the final Au coating step optically resembles gold NC structures. A small bump corresponding to the plasmon of silver is also visible at ˜400 nm in this particular sample. This transformation is also highlighted in FIG. 9(a-c). FIG. 9(a-c) depict the appropriate growth of gold on the superconducting NC structures for obtaining the NC structures with transition temperatures at 323 K, 234 K and 150 K at zero magnetic fields. The superconducting transition temperatures were measured by examining film resistance, as shown in FIG. 15(a-c).

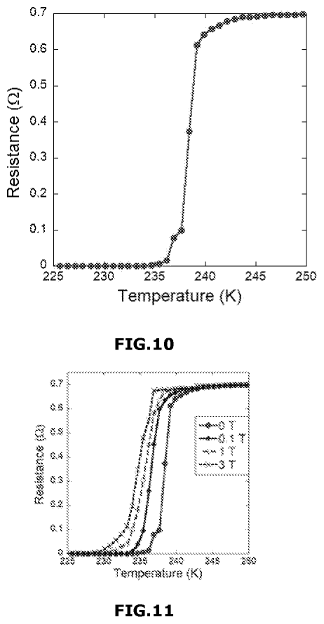

The negligible optical dissipation is further supplemented by the existence of low resistance in the superconducting state. This is most conveniently measured for assemblies using devices that are described below. Films of superconducting NC structures of the present invention show transitions to superconductivity below a certain critical temperature, as shown in FIG. 10. The residual resistance is a measurement error that is attributed to the resistivity measurement system. This error is caused due to small contact resistances that form at various parts of the measurement circuit. In the given example, the transition is observed to occur at 238 K.

Consistent with the attainment of a superconducting state, the transition temperature is a strong function of the magnetic field. As shown in FIG. 11, the transition systematically falls to 234 K for a 3T field.

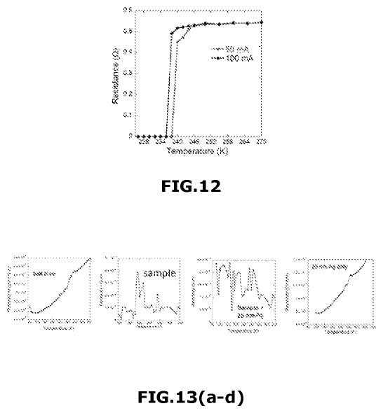

The transition temperature as measured using sample resistance is also a function of the current. This is shown in FIG. 12, where a 100 mA drive current leads to a 236 K transition as opposed to a 238K transition at 3.2 mA driving current.

In contrast to the low resistivity and resistance observed for samples in their superconducting state, 20 nm thick metallic gold films show a resistivity of ˜2×10⁻⁷ Ohm-m (FIG. 13a). Superconducting sample films of similar thickness show resistivities as low as 1×10⁻¹¹ Ohm-m, limited essentially by the measurement setup (FIG. 13b). The sample shown in this figure has a transition temperature well above the accessible temperature range in this setup. The measured resistivity is further reduced by the infiltration of 25 nm Ag into the superconducting film. This is accomplished by evaporation. The resultant resistivity is shown in FIG. 13c (around 10⁻¹¹ Ohm-m). The resistivity of a 25 nm evaporated Ag film is as low as 9×10⁻⁸ Ohm-m (FIG. 11(d)).

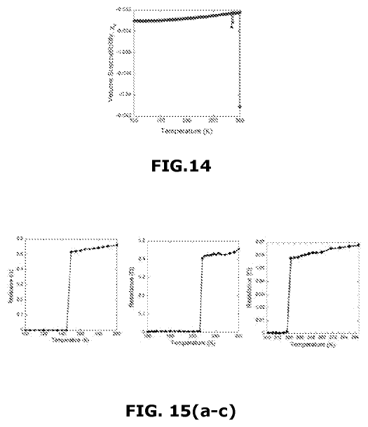

The magnetic volume susceptibility of such samples was measured and found to be −0.034, as shown in FIG. 14. This is a far stronger diamagnet than any known non-superconducting material.

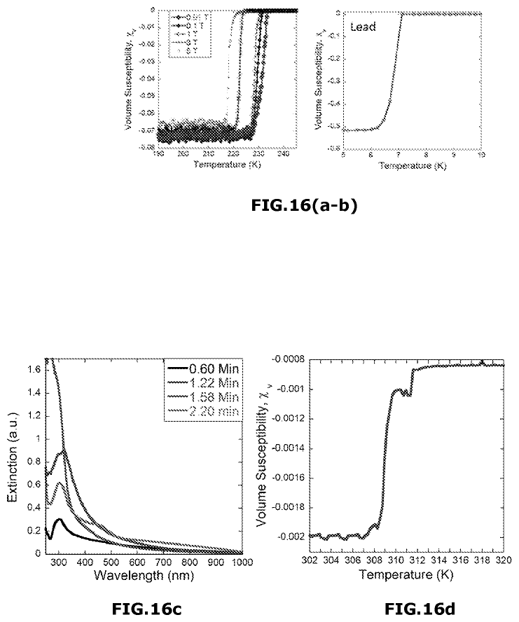

FIG. 16(a) depicts the volume susceptibility of an superconducting NC that exhibits a transition at 230 K. Increasing field causes a decrease in the transition temperature to 218 K at 5 T. In its superconducting state the superconducting NC is characterized by a volume susceptibility of −0.075. In contrast, as shown in FIG. 16(b), a 100 mg lead pellet exhibits a volume susceptibility of −0.5 at 5 K (below its transition temperature). As shown in FIG. 16(c) where the formation of silver core at different time intervals permits the varying the size of the silver core. The optical spectra as shown in this figure is of exemplary Au—Ag superconducting NCs of the present invention. In this figure, the time shown corresponds to the interval between mixing of silver nitrate and CTAB solutions and the addition of borohydride. The optimal spectrum 1.58 Min for the NC is also seen and where all others are of lesser varying degrees. The formation of core of silver core at different time frame is performed. The features allows varying the size of the silver core. In this figure optical spectra of Au—Ag superconducting NCs of the present invention are shown, where the time shown corresponds to the interval between mixing of silver nitrate and CTAB solutions and the addition of borohydride. The 1.58 Min spectrum is optimal, while all others are poorer to varying degrees.

FIG. 16(d) depicts volume susceptibility of the exemplary superconducting nanocrystals with transition temperature at 310 K for the exemplary sample of Au/Ag NCs of the present invention.

In a further aspect of the present invention, the present subject matter provides a superconducting NC and a NC based device. The NC based device comprises NC structures and substrates. The device comprises at least a substrate for arranging the superconducting nanocrystal structure. In the device of the present invention, the superconducting nanocrystal structure is configured to be arranged in an aggregated or sintered form not only to preserve the internal core structure but also to facilitate the loss of individual identities of the particles of the selected metallic materials. Devices based on superconductors may comprise of the superconductor in the form of a wire or fiber, or as a film. In one implementation, wires of superconductor are covered with insulator and wound around a core. Current in this configuration causes the emergence of a magnetic field in the core. In other implementations, the phase differences between two weakly connected superconductors gives rise to a current. In another implementation, one superconductor is used to induce superconductivity in a material that is itself not superconducting under the applicable conditions. In each of these cases, the superconductor being used exhibits its superconducting state at elevated temperatures.

In a further aspect of the present invention, the substrate is inert and provides a mechanical support to the superconducting nanocrystal structure. The substrate can be configured to provide a path for electron flow, or for the transmittal or exclusion of electric and magnetic fields. The material for the substrate can be a polymer (polyethene, polystyrene, Bakelite or a like material), a rubber (such as a silicone or nitrile), a glass (such as a borosilicate glass), or a metal such as copper, iron, nickel or aluminum, or even an alloy or combination of any of the above.

In yet another aspect of the present invention, the device that is incorporated with the superconducting nanocrystal structure relies on the transfer of charges or a current of charges between two points located within the device. The transit of current between at least two points within the device takes place along a path that comprises the superconducting nanocrystal or its aggregate or a composite comprising the superconducting nanocrystal.

In yet another aspect of the present invention, the device relies on the measurement of the different phases of the wave function on distinct superconducting regions in the device. Each continuous superconducting region is associated with a definite phase. The phase differences between two different superconducting domains gives rise to a measurable Josephson current that makes the determination of phase differences possible. Low temperature versions of such devices are already used to sense magnetic fields, and are also important from the view of quantum computation. The superconductors of the present invention with higher-than-room-temperature-transition-temperatures allows for the construction of such devices at room temperature.

In another implementation, the device relies on superconducting regions to exclude electric and magnetic fields from a certain region. Superconductors with anti-symmetric spin pairing exclude magnetic fields from the bulk of the superconductor. Being perfect conductors, superconductors also exclude electric fields from their bulk. Thus superconductors may be used in shielding devices where internal components are isolated from electric and magnetic fields by a superconducting layer.

In another implementation, the device utilizes the superconductor to guide magnetic fields along the length of the superconducting region. Superconductors with symmetric spin pairing can interact with magnetic fields in a manner such that the superconducting state is stabilized relative to its condition in absence of the field. In this situation, the superconductor can serve as a guide for allow transmission of magnetic fields, similar to ferromagnetic materials. In another implementation, the device utilizes a current flow in the superconducting region to generate a magnetic field. Current flows generate magnetic fields, and this effect is used to make electromagnets. Superconducting electromagnets dissipate very little power, and are consequently used to attain high magnetic fields such as are useful for medical diagnostics. Due to the absence of any known superconductors that have transitions at or above room temperature, extensive cooling is required to make such magnets function. The availability of room temperature superconductors will thus enable the manufacture of simpler magnetic field generating devices. Secondly, the potential of symmetric spin pairing in such superconductors will additionally boost their ability to generate magnetic fields.

The superconducting nanocrystal structure can also be deposited on the substrate to obtain the desired device. Deposition of the superconducting nanocrystal structure can be done by deposition techniques such as drop casting or spin coating from colloidal dispersions and the like. The inert substrate provides mechanical support to the superconducting nanocrystal structure while minimally affecting its properties.

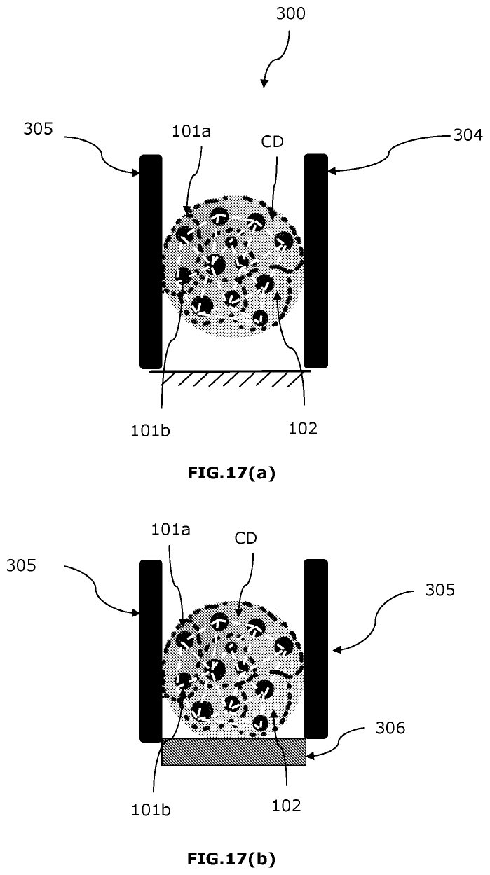

FIGS. 17(a-b) depict a superconducting device (300) comprising superconducting blocks (100) that are advantageously disposed on a substrate (306). The substrate (306) may be variously conductive or non conductive. The material for the substrate (306) is selected from an electrically conducting material, an insulator or a semiconductor. Alternately, the material for the substrate (306) is selected from polymer, preferably polyethene, polystyrene, bakelite, rubber, preferably a silicone, nitrile, glass, preferably a borosilicate glass, a metal, preferably copper, iron, nickel or aluminum, or an alloy of the metals, or a combination thereof.

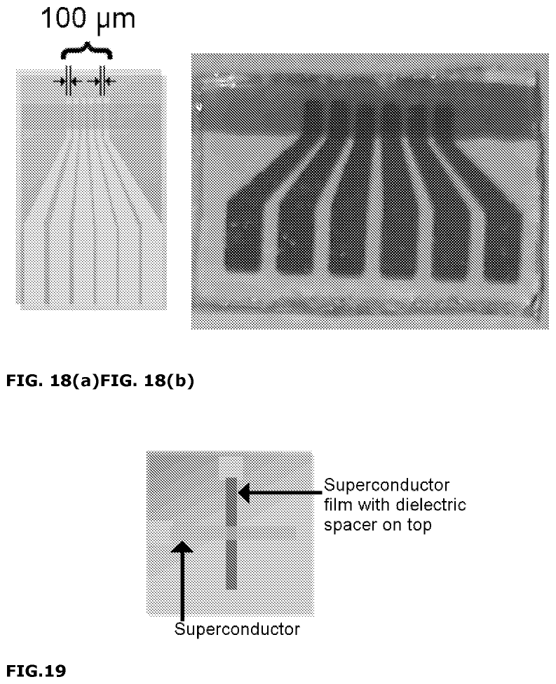

FIGS. 18(a-b) depict exemplary devices using the superconducting NCs of the present invention, where FIG. 18(a) and (b) is a schematic and photograph of a device, respectively, which relies on current flow through a superconductor film. The device is used to characterize the resistance of superconducting films. The device has six probes to enable determination of sample resistance in a contact resistance-free manner. The probes are composed of 100 nm thick metallic gold. The superconducting NC of the present invention was deposited on this device. It is seen, that the resistance of films of such NCs can become vanishingly small even at very high temperatures, such as room temperature and beyond. Thus, it is thus demonstrated that such materials could be employed as current transporting layers in situations where losses are undesirable.

FIG. 19 is a schematic of a device that relies on tunneling into a superconductor film. This Figure shows a device used to characterize the superconducting gap. The device can exhibit Giaver as well as Josephson tunneling. Due to the use of NCs of the present invention, it is possible to observe such phenomena at room temperature, under ambient conditions.

Due to their superconductivity at high temperatures, the superconducting NCs of the present invention may be utilized to create magnets, qubits for quantum computation, current carrying interconnects in power grids as well as small scale devices, field generators in maglev trains, as power storage devices, field sensors and as electromagnetic field guides, concentrators and shields, In each case, the superconductor based device may be designed to be operational at room temperatures or above.

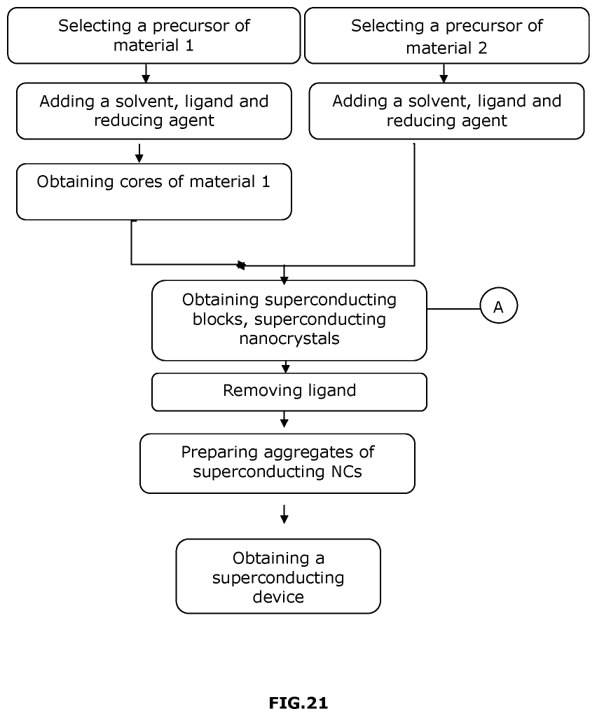

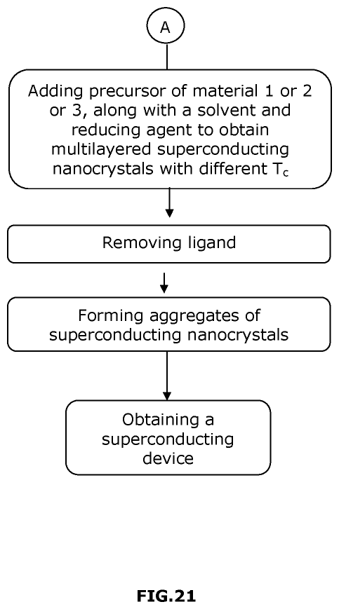

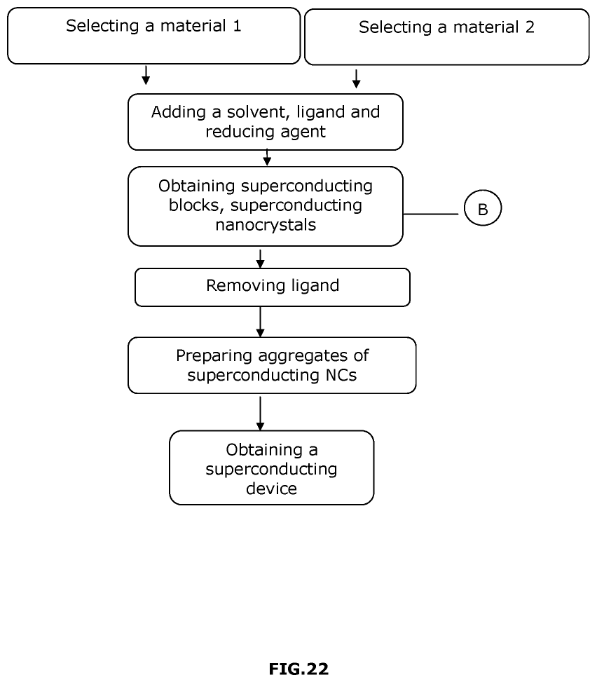

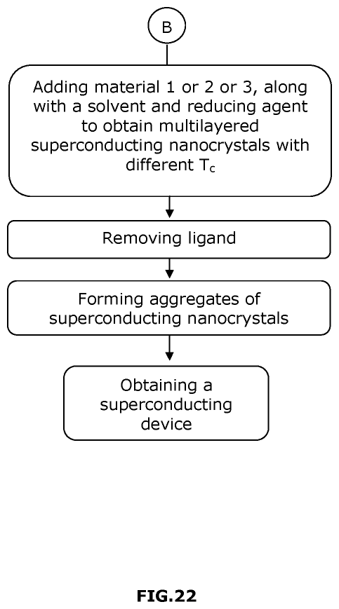

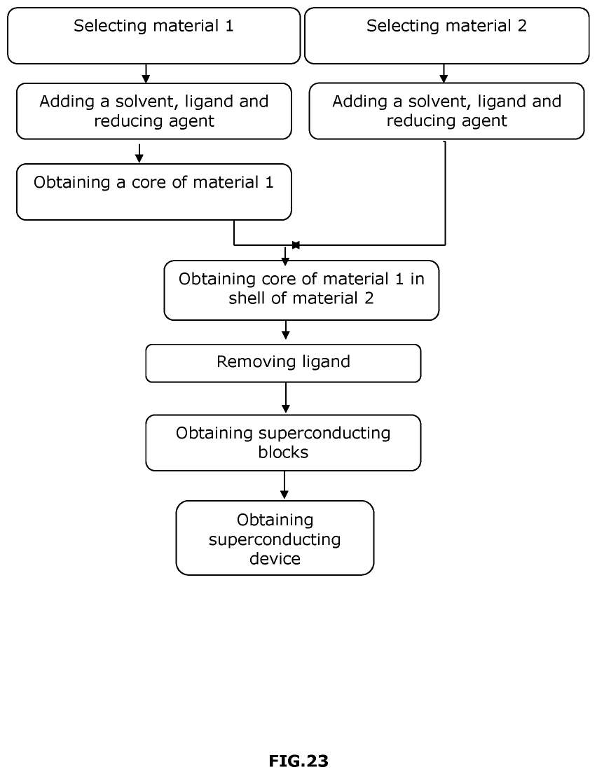

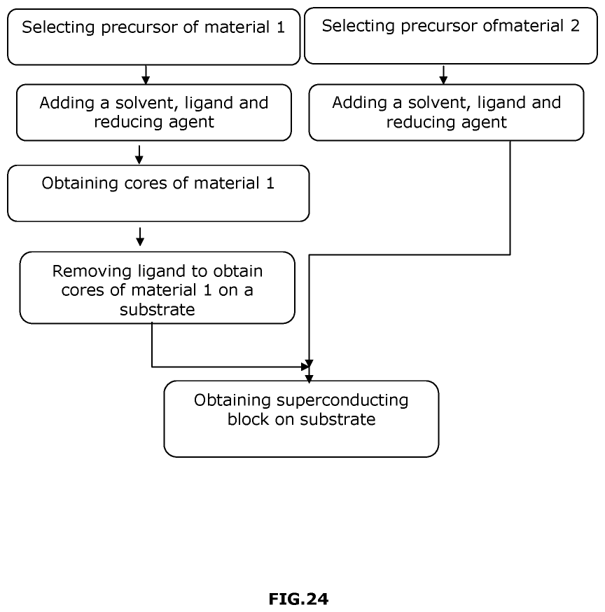

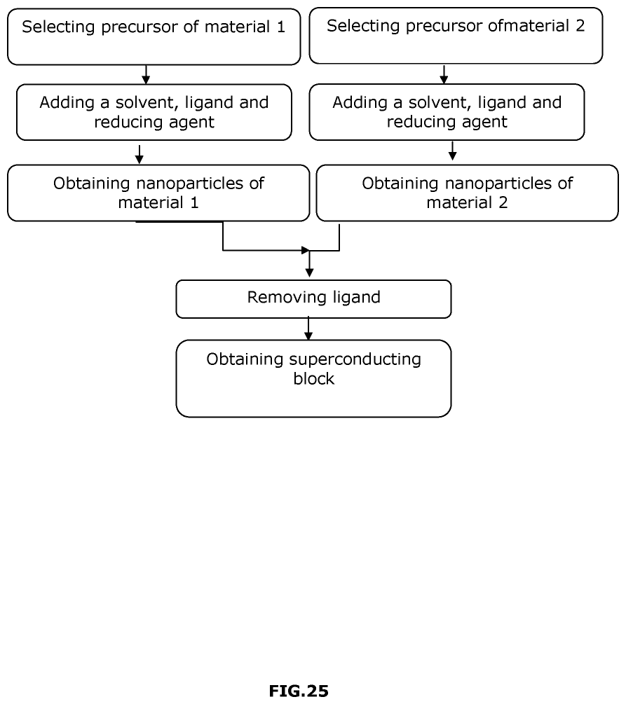

In yet another aspect of the present invention, a process for preparation of the superconducting nanocrystal structure of the present invention are now described by referring to FIGS. 21-25.

The process of making the superconducting nanocrystal involves picking core and shell materials. Cores are subsequently formed out of the core material. Following this step, cores are embedded into the shell material. This process may be variously accomplished either by building the shell on top of a core and subsequently causing shells of different cores to merge into a single shell by aggregation or through continued growth of the shell. Alternately, the incorporation of a plurality of cores into a shell may be accomplished by causing the precipitation of cores on to the substrate along with the shell material. In one implementation of this scheme, the core is deposited onto a substrate that may be a planar surface, an elongated surface, preferably a wire or else a nanoparticle. In another implementation of this scheme, the core is deposited onto preformed nanoparticles of the shell material and additional shell material is grown on top of this structure.

In the present invention, the present invention, the control of the transition temperature of the superconductor is performed by regulating the deposition of number of layers, the number and size of inner centers per unit volume of material, the nature of the center and the matrix material. Selection of materials with lower volta potential difference, causes a depression in the transition temperature. Similarly, using cores with non-optimal size, either too large or too small, lead to lower transition temperatures. Once a certain structure is synthesized, it is possible to regulate its transition temperature by overgrowing another metal or any one of the two metals over the structure. This growth may be done in solution or after depositing the structures as a film. This causes a decrease in the transition temperature, that is dependent on the metal being deposited, with lower volta potentials causing lesser decrease. A stronger decrease in transition temperatures is observed, when a large quantity of the desired material is deposited on the nanocrystal. In effect, the lower loading levels of 0.3-2 nm grains in the second material causes the transition temperature to become lower. The transition temperature may also be controlled by regulating superconducting nanocrystal size and state of aggregation or by bringing materials that exist in a non-superconducting state in proximity or contact with the particles. This may be achieved by either overgrowth of a material onto the superconducting nanocrystal, by the incorporation of the material into the superconducting nanocrystal in form of a coating or its incorporation into an assembly of superconducting nanocrystals.

By using the process steps of the present invention, exemplary superconducting NC structures with different critical temperatures are prepared. For example, as shown in FIGS. 15(a-c), the NC structures with transition temperatures of 150K (FIG. 13(a)), 222 K (FIG. 15(b)) and 325 K (FIG. 13(c)). The exemplary NC as shown in FIG. 13(c) is at a temperature that is well above the room temperature. In each case, the lower transition temperature is attained by coating superconducting materials with a high transition temperature with a metal (either gold or silver). The NC structures as shown in FIGS. 13(a-c) are prepared as follows: We start from a superconducting NC with an exemplary molar ratio of 5.43:1. Gold is progressively over coated on this superconducting nanocrystal, causing a decrease in the transition temperature. The superconducting NC as shown in FIG. 13(a) has a gold to silver molar ratio of 6.41:1. Whereas, for the NC as shown in FIG. 13(b), the ratio is 5.95:1 mmole of gold and silver. For FIG. 13(c), the ratio is 5.583:1. A smaller amount of over coating thus leads to a higher transition temperature.

The process steps for the preparation of the superconducting nanocrystal structure include generating conditions where one of the constituent materials (metal), forms nanoclusters of the desired size. These nanoclusters are subsequently encapsulated into the other selected material (metal). In the event, both the materials are forming nanoparticles, the process steps are modified to enable the aggregation of these materials.

The superconducting nanocrystal can be formed into aggregates by sintering the prepared superconducting nanocrystals thermally or chemically. Thermal sintering is accomplished by heating the deposited superconducting nanocrystal structure material to temperatures above the room temperature such that the ligands are degraded or otherwise eliminated. Alternatively, the process involves adding chemical reagents to dissolve away or to chemically degrade ligands and extraneous molecules around the superconducting nanocrystal structure.

In the process steps of the present invention, selected metals are formed into corresponding nanoparticles of desired size, which is preferably in the range of 0.3-2 nm size, by adding a ligand and a reducing agent. Alternately, the nanoparticles are also obtained in the presence of immiscible solvents, to create nano or micro droplets that template growth. These nanoparticles are then reduced to the desired metal or alloy. Additional steps are adopted to regulate the transition temperature T_{c} and to form the superconducting nanocrystal structure. The high temperature superconducting nanocrystal structure that is formed is treated with a ligand remover to form corresponding aggregates. These aggregates may be transformed into films, wires, pellets etc. or be otherwise molded.

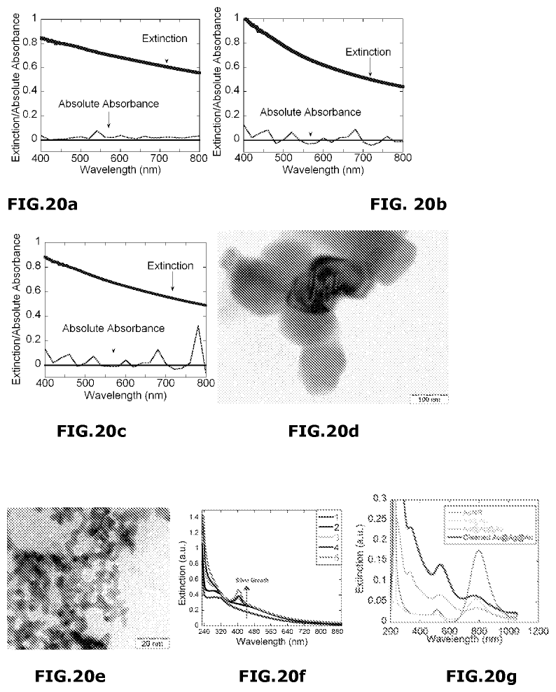

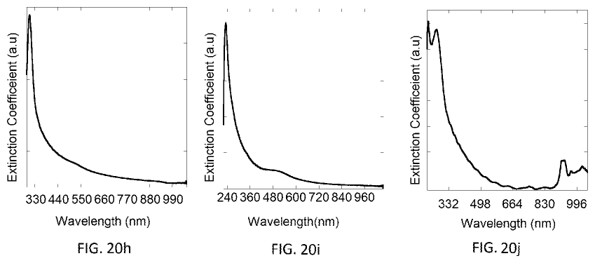

These procedures may be adopted to prepare other exemplary superconducting NCs. For example, FIG. 20(a-c) show superconducting Pt—Cu, Mn—Cu and Pd—Cu NCs respectively. Each of these has optical properties analogous to Au—Ag NCs. FIG. 20(d) and FIG. 20(e) show the TEM images of Mn—Cu and Au—Cu NCs. FIG. 20(f) shows the optical properties of superconducting Au—Ag/Ag NCs. Finally, FIG. 20(g) shows an example where the superconducting NCs are rod like.

The present subject matter will now be illustrated with a working example, which is intended only to illustrate the working of disclosure and not intended to be taken restrictively to imply any limitations on the scope of the present disclosure.

### Example 1: Synthesis of Au—Ag Superconducting Nanocrystal Structure

Synthesis of Gold (Au) nanosphere of 8-10 nm:

Monodisperse Gold nanospheres of 8-10 nm were synthesised by a seed mediated process. In this process 5 ml of 0.5 mM HAuCl₄ (Gold (III) chloride trihydrate, >99.9%) was added to 5 mL of 0.1 M CTAB (Cetyltrimethylammonium, >99%) solution. The solution was stirred vigorously. To it was added 0.6 mL of 0.1 M NaBH₄ (sodium Borohydride, >96%) rapidly. The final colour of the solution obtained was brownish indicating the formation of 3 nm gold nanocrystals seed. This seed was then used for synthesizing 8-10 nm gold nanospheres. A growth solution was prepared comprising of 500 ml of 5 mM HAuCL₄, 0.1 M CTAB in 500 mL water and 3 ml of 0.0788 M ascorbic acid. To the growth solution, 8 mL of Au seed was added. The solution was shaken well and kept for 5 hrs.

### Synthesis of Nanocomposite:

The obtained Gold nanosphere solution was cleaned through centrifugation with water. The precipitate was re-dispersed in 10 mL 0.1 M CTAB solution in water and was taken in a conical flask. The solution was stirred properly. Next 1 mL of 1 mM silver nitrate solution was added into the solution (over approximately 5 seconds) and a timer for the reaction was switched on once the addition was complete. When the time reached 1 min, 2 mL of 0.1 M NaBH₄ was added rapidly followed by drop wise addition of 1 ml of 1 mM HAuCl₄ solution. The final product was tracked through its UV-Visible spectrum.

### Synthesis of Various Grown Sample:

To grow Au layer on the sample, the ungrown sample was first cleaned with water through centrifugation. The centrifugation was carried out twice. The obtained precipitate was then re-dispersed in 10 mL of 0.1 M CTAB solution. The solution was taken in 25 ml conical flask and requisite amount of 1 mM HAuCl₄ was added drop wise, 10 μL/3 min. Before the addition of HAuCl₄ the solution was made reducing by adding NaBH₄ solution (2 ml 0.1 M). For expected superconducting transition temperature following amount of 1 mM HAuCl₄ were added: 125 μL for 323 K, 231 μL for 234 K and 425 μL for 150 K respectively (rate of addition: 10 μL/5 min). The reaction was stopped immediately after the addition of HAuCl₄ by centrifugation. All the samples were stored in Sodium Borohydride (in methanol, LR Grade), reducing solution inside the glove-box.

### Cleaning of Samples:

Several batches of such samples were synthesized and mixed together. The quality of the sample from each batch was decided through UV visible spectra. The sample was cleaned through centrifugation with water. The centrifugation was done five times. The obtained precipitate was collected in 30 ml vial and was kept for drying. To the dried sample, 5 mL of CHCl₃ (Chloroform, LR grade) was added and the solution was sonicated for 10 min. The solution was kept in CHCl₃ solution for 4 hrs. After 4 hours the solid sample was separated from CHCl₃ through centrifugation and a fresh CHCl₃ was added. The previous process of sonication and the addition of CHCl₃ after every four hours was carried out for 2 days. On the next step, the sample in CHCl₃ is centrifuged and precipitated. The precipitate was kept for drying. Once dried the solid sample was washed with acetone several time and left for drying. To the dried sample 5 mL of 1 M KOH (Potassium hydroxide) solution in water was added. The sample in KOH solution was sonicated thoroughly and was kept for half an hour. Every half an hour KOH solution was changed and sonicated. The process was repeated for a day. The final obtained mass (fine grains) of aggregated superconducting NCs looked grey-whitish in color with metallic luster. The fine grains of superconductor were stored in the reducing environment of sodium borohydride solution inside the glove-box. Macroscopic samples of Au—Ag superconducting NCs show ferromagnetism upon exposure to oxygen. This may be reversed by exposure to reducing agents such as sodium borohydride.

### Example 2: Synthesis of Mn-Cu_Superconducting Nanocrystal Structure

A microemulsion system was made by mixing 1 gm sodium dodecyl sulfate (SDS, ACS reagent≥99%), 3 ml butan-1-ol (LR Grade), 6.5 ml n-hexane (HPLC & Spectroscopy Grade) and 1 ml of 0.0009 (M) Copper(II) chloride (CuCl₂.2H₂O, ACS reagent≥99%) aqueous solution. Form this clear solution 2 ml was taken out in a pipette and spectra was measured taking air as reference. To this solution 10 micro litres of freshly prepared 0.2% Sodium borohydride (NaBH₄ ACS reagent≥98%) solution was added in open atmospheric condition at room temperature. The solution became yellow of which spectra were recorded using similar way mentioned before. From the spectra it was estimated that the size of copper (Cu) cores are ˜0.7 nm. Then 1 ml of 0.0009 (M) Manganese(II) chloride tetrahydrate (MnCl₂. 4H₂O, ACS reagent≥98%) solution along with 1 ml of excess NaBH₄ (>20%) were added very rapidly. To this mixture 10 ml of 0.3 (M) cetrimonium bromide (CTAB ACS reagent 98%) solution was added. Throughout the reaction the entire solution was stirred continuously at 400 rpm. After completion the solution turned white, indicating the formation of superconducting Mn—Cu NCs. If settled down, two different layers of solvent got separated out from the entire mixture. The upper part which is soluble in organics was greyish in colour whereas the lower part which is soluble in water was white in colour leaving aggregates at the interface. To make a clear solution, 10 ml of ethanol (EtOH Absolute 99.9%) was added. The aggregates were collected by centrifugation which leaves a black precipitate). When the precipitate was sonicated with water it gives a white solution which showed scattering. Spectrum of this solution was taken using water as reference. The similar scattering effect was observed increasing the size of the Cu-cores, prepared by following the same synthetic procedure, up to 2 nm.

### Example 3: A Direct Synthesis of Directly Prepare a Mn—Cu Macroscopic Aggregates

A microemulsion system was made by mixing 1 gm sodium dodecyl sulfate, (ACS reagent≥99%), 3 ml butan-1-ol (LR Grade), 6.5 ml n-hexane (HPLC & Spectroscopy Grade) and 1 ml of 0.0009 (M) Copper(II) chloride (CuCl₂.2H₂O, ACS reagent≥99%) aqueous solution. Form this clear solution 2 ml was taken out in a pipette and spectra was measured taking air as reference. To this solution 10 micro litres of freshly prepared 0.2% Sodium borohydride (NaBH₄, ACS reagent≥98%) solution was added in open atmospheric condition at room temperature. The solution became yellow of which spectra were recorded using similar way mentioned before. From the spectra it was estimated that the size of copper (Cu) cores are ˜0.7 nm. To this yellow solution 10% Polyvinylpyrrolidone (PVP, ACS regent, average molecular weight 40,000) solution was added. Then 1 ml of 0.0009 (M) Manganese(II) chloride tetrahydrate (MnCl₂.4H₂O, ACS reagent≥98%) solution along with 1 ml of excess NaBH₄ (>20%, ACS reagent≥98%) were added very rapidly. Throughout the reaction the entire solution was stirred continuously at 400 rpm. If settled down, two different layers of solvent got separated out from the entire mixture. The upper part which is soluble in organics was greyish-brown in colour whereas the lower part which is soluble in water was yellow in colour leaving brown aggregates at the interface. The entire solution was stirred once and centrifuged. After centrifugation, small black particles of Mn—Cu superconductor were observed at the bottom of the vial. These are observed to be strongly ferromagnetic . . . .

### Example 4: A Direct Synthesis of Directly Prepare a Au—Cu Superconducting Nanocrystal Structure

A microemulsion system was made by mixing 1 gm sodium dodecyl sulfate (SDS, ACS reagent≥99%), 3 ml butan-1-ol (LR Grade), 6.5 ml n-hexane (HPLC & Spectroscopy Grade) and 1 ml of 0.0009 (M) Copper(II) chloride (CuCl₂.2H₂O, ACS reagent≥99%) aqueous solution. Form this clear solution 2 ml was taken out in a pipette and spectra was measured taking air as reference. To this solution 10 micro litres of freshly prepared 0.2% Sodium borohydride (NaBH₄, ACS reagent≥98%) solution was added in open atmospheric condition at room temperature. The solution became yellow of which spectra were recorded using similar way mentioned before. From the spectra it was estimated that the size of copper (Cu) cores are 0.7 nm. Then 1 ml of 0.0009 (M) Hydrogentetrachloroaurate(III)trihydrate (HAuCl₄.3H₂O, ACS 99.99% metal basis) solution along with 1 ml of excess NaBH₄ (>20%) were added very rapidly. To this mixture 10 ml of 0.3 (M) Cetrimonium bromide (CTAB, ACS reagent≥98%) solution was added. Throughout the reaction the entire solution was stirred continuously at 400 rpm. After completion the solution turned white, indicating the formation of superconducting Au—Cu NCs. If settled down, two different layers of solvent got separated out from the entire mixture. The upper part which is soluble in organics was greyish in colour where as the lower part which is soluble in water was white in colour leaving aggregates at the interface. To make a clear solution, 10 ml of Ethanol (EtOH, Absolute 99.9%) was added. The aggregates were collected by centrifugation which leaves a black precipitate. When the precipitate was sonicated with water it gives a white solution which showed scattering. Spectrum of this solution was taken using water as reference. The similar scattering effect was observed increasing the size of the Cu-cores, prepared by following the same synthetic procedure, up to 2 nm.

### Example 5: A Direct Synthesis of Directly Prepare a Pd—Cu Superconducting Nanocrystal Structure

A microemulsion system was made by mixing 1 gm sodium dodecyl sulfate (SDS, ACS reagent≥99%) 3 ml butan-1-ol (LR Grade), 6.5 ml n-hexane (HPLC & Spectroscopy Grade) and 1 ml of 0.0009 (M) Copper(II) chloride (CuCl₂.2H₂O, ACS reagent≥99%) aqueous solution. Form this clear solution 2 ml was taken out in a pipette and spectra was measured taking air as reference. To this solution 10 micro litres of freshly prepared 0.2% Sodium borohydride (NaBH₄, ACS reagent≥98%) solution was added in open atmospheric condition at room temperature. The solution became yellow of which spectra were recorded using similar way mentioned before. From the spectra it was estimated that the size of copper (Cu) cores are ˜0.7 nm. Then 1 ml of 0.0009 (M) Potassium tetrachloropaladate(II) (K₂PdCl₄, ACS≥99.99% trace metal basis) solution along with 1 ml of excess NaBH₄ (>20%) were added very rapidly. To this mixture 10 ml of 0.3 (M) Cetrimonium bromide (CTAB ACS reagent≥98%) solution was added. Throughout the reaction the entire solution was stirred continuously at 400 rpm. After completion the solution turned white indicating the formation of superconducting Pd—Cu NCs. If settled down, two different layers of solvent got separated out from the entire mixture. The upper part which is soluble in organics was greyish in colour whereas the lower part which is soluble in water was white in colour leaving aggregates at the interface. To make a clear solution, 10 ml of Ethanol (EtOH, Absolute 99.9%) was added. The aggregates were collected by centrifugation which leaves a black precipitate. When the precipitate was sonicated with water it gives a white solution which showed scattering. Spectrum of this solution was taken using water as reference. The formation of superconducting Pd—Cu NCs was observed even by increasing the size of the Cu-cores, prepared by following the same synthetic procedure, up to 2 nm.

### Example 6: A Direct Synthesis of Pt—Cu Superconducting Nanocrystal Structure

A microemulsion system was made by mixing 1 gm sodium dodecyl sulfate (SDS, ACS reagent≥99%), 3 ml butan-1-ol (LR Grade), 6.5 ml n-hexane (HPLC & Spectroscopy Grade) and 1 ml of 0.0009 (M) Copper(II) chloride (CuCl₂.2H₂O, ACS reagent≥99%) aqueous solution. Form this clear solution 2 ml was taken out in a pipette and spectra was measured taking air as reference. To this solution 10 micro litres of freshly prepared 0.2% Sodium borohydride (NaBH₄, ACS reagent≥98%) solution was added in open atmospheric condition at room temperature. The solution became yellow of which spectra were recorded using similar way mentioned before. From the spectra it was estimated that the size of copper (Cu) cores are ˜0.7 nm. Then 1 ml of 0.0009 (M) Chloroplatinic acid hydrate (H₂PtCl₆.xH₂O molecular weight 409.8 anhydrous basis, ACS≥99.9% trace metal basis) solution along with 1 ml of excess NaBH₄ (>20%) were added very rapidly. To this mixture 10 ml of 0.3 (M) Cetrimonium bromide (CTAB, ACS reagent≥98%) solution was added. Throughout the reaction the entire solution was stirred continuously at 400 rpm. After completion the solution turned white indicating the formation of superconducting Pt—Cu NCs. If settled down, two different layers of solvent got separated out from the entire mixture. The upper part which is soluble in organics was greyish in colour where as the lower part which is soluble in water was white in colour leaving aggregates at the interface. To make a clear solution, 10 ml of Ethanol (EtOH, Absolute 99.9%) was added. The aggregates were collected by centrifugation which leaves a black precipitate. When the precipitate was sonicated with water it gives a white solution which showed scattering. Spectrum of this solution was taken using water as reference. The formation of superconducting Pt—Cu NCs was observed even by increasing the size of the Cu-cores, prepared by following the same synthetic procedure, up to 2 nm.

### Example 7: A Synthesis of Ag—Au Superconducting Nanocrystal Structure

Hexadecyltrimethylammonium bromide from Sigma (≥98% pure), potassium iodide from Sigma-Aldrich (ACS reagent, ≥99.0% pure), silver nitrate from Sigma-Aldrich (ACS reagent, ≥99.0% pure), sodium borohydride powder from Sigma-Aldrich (≥98.0% pure), hydrogentetrachloroaurate(III)trihydrate from Sigma-Aldrich (ACS, 99.99% pure, metal basis) were used as received without any further purification. All the aqueous solutions have been prepared in milli-Q water to avoid any trace of metal contamination. In first step, aqueous solutions of 0.1 M hexadecyltrimethylammonium bromide[CTAB] (5 mL), 0.1 M of potassium iodide (200 μL) and 1 mM silver nitrate (5 mL) were mixed. The mixture was continuously stirred at 900 rpm for 4 min 30 seconds to produce the silver halide clusters (Make sure reaction should be stopped before white coloration). Absorption spectra have been recorded after each successful reaction to know the exact sizes of the silver halide cores. Proper size cores have been used for second step of reaction. In second step, a separate vial with 5 mL aqueous solution of gold nano-sphere [Optical Density (OD) of 0.1 at 530 nm] and 2 mL aqueous solution of 0.1 M sodium borohydride were taken. The resulting solution was stirred continuously at 900 rpm in presence of a 14 W CFL bulb. The light source is present 1 m away from the reaction vessel. Now freshly prepared silver halide cluster solution (around 10 mL) and 2 mL aqueous solution of 0.1 mM hydrogentetrachloroaurate(III)trihydrate [HAuCl₄] have been added simultaneously to the nano-sphere solutions over a period of 8 minutes. Addition rate has been monitored constantly to avoid any independent or side nucleation of Ag/Au nanoparticles. The starting solution color was pink, but with initial addition of halide cluster and HAuCl4 in reducing environment it turns into a colorless state with slight white haze. Finally it converts into a complete white color solution. A typical optical spectrum is shown in FIG. 20h.

### Example 8: A Direct Synthesis of Au Coated Single Ag Cores and their Assembly into a Superconductor

Hexadecyltrimethylammonium bromide (CTAB, ≥98% pure,), potassium iodide (KI, ACS reagent, ≥99.0% pure), silver nitrate (ACS reagent, ≥99.0% pure), sodium borohydride powder from (NaBH₄, ≥98.0% pure), hydrogentetrachloroaurate(III)trihydrate (HAuCl₄, ACS, 99.99% pure, metal basis), Sodium ascorbate. All chemicals were purchased from sigma used as received without any further purification. Isopropyl alcohol (IPA, AR ACS) was purchased from SDFCL. All the solutions have been prepared using milli-Q-water. Step 1: Silver cores were synthesized by making initial silver halide clusters, then the preformed halide clusters were reduced by using sodium borohydride. The initial silver halide clusters were prepared by adding mixture of 10 ml CTAB (0.1 M) and 40 microlitres of 0.1 M KI (here KI was added to obtained desired clusters size) into 5 ml of AgNO₃ (1 millimolar) and mixture was stirred for 1 min 22 sec and 2 ml of 0.1M ice-cold sodium borohydride was added. The Borohydride reduces preformed silver halide clusters into silver cores. Absorption spectra has been recorded after the reactions to know the exact sizes of the Ag cores. The proper sized silver cores has been used for second step. Step 2: Gold was coated on the above silver cores by adding 1 ml of 1 millimolar HAuCl₄. Optical data of a single Ag core embedded in Au does not show evidence of superconductivity. An exemplary spectrum is shown in FIG. 20i. To crash the sample approximately 6 ml of IPA was added and centrifuged. Absorption Spectra of gold coated silver core were taken before and after IPA treatment. Once deposited into a film through means described above, such structures yield a resistivity three orders of magnitude below that of metallic bulk gold, being essentially limited by the measurement apparatus.

### Example 9: A Direct Preparation of Ag—Au Superconducting Films

Synthesized silver cores (Step 1) from the above method was drop casted on the glass plate. Then, cores were allowed to fall on glass plate by switching on 14 W CFL bulb for approximately 15 to 20 min. Extra CTAB ligand was washed off by using milli-Q-water and dried. To embed gold into this film a drop of 1 millimolar HAuCl₄ and a drop of 1 M sodium ascorbate was simultaneously added (Here Sodium Ascorbate is used to reduce Au³⁺ into Au). Film was again kept for drying under 14 W CFL bulb for approximately 15 to 20 min. The above steps were repeated for 3 to 4 times. And dried films were used for further electrical measurements.

### Example 10: A Direct Synthesis of Ag—Au Superconducting Grains

Synthesis of large grains of Ag cores in Au shell. 5 ml of 1 (mM) Hydrogentetrachloroaurate (III) trihydrate (HAuCl₄, ACS, 99.99% pure, metal basis) was mixed with 5 ml of 0.1 (M) Potassium bromide (ACS reagent, ≥99.0% pure) solution. To this 40 microlitres of 0.1 (M) L-Ascorbic acid (Sigma Aldrich 99%) was added with continuous stirring. Next 1 ml of 1 (mM) of Silver nitrate (ACS reagent, ≥99.0% pure) and 2 ml of 0.1 (M) ice-cold Sodium borohydride (NaBH₄, ≥98.0% pure), was added simultaneously. The reaction mixture was frozen immediately and moved into the glove box for further analysis. Such grains are strongly diamagnetic in the ambient and are visibly repelled by a hand held permanent magnet.

### Example 11: A Synthesis of Ag Cores in a CuO Shell

Hexadecyltrimethylammonium bromide from Sigma (≥98%), potassium iodide from Sigma-Aldrich (ACS reagent, ≥99.0%), silver nitrate from Sigma-Aldrich (ACS reagent, ≥99.0%), sodium borohydride powder from Sigma-Aldrich (≥98.0%), copper(II) sulphate pentahydrate from Sigma-Aldrich (ACS reagent, ≥98.0%), potassium hydroxide pellets from SDFCL (AR grade) and Propan-2-ol (iso-Propyl alcohol, IPA) from SDFCL (AR, ACS reagent) were used as received. Milli-Q water was used as a solvent. Aqueous solutions of 0.1M hexadecyltrimethylammonium bromide (10 mL), 0.1M of potassium iodide (40 μL) and 1 mM silver nitrate (5 mL) were mixed in the presence of 14 W CFL bulb. The mixture was continuously stirred for 2 min 30 seconds followed by addition of 2 mL of 0.1M aqueous solution of sodium borohydride to produce the silver cores. To the above solution of silver core simultaneously 1 mL of 1 mM acidic aqueous solution of copper sulphate (pH=3) was added and 5 mL of 0.1M alcoholic KOH solution (KOH was dissolved in IPA) was added with continuous stirring. The final solution was heated to around 80° C. for 15 minutes. The obtained precipitate was collected through mild centrifugation.

### Example 12: A Direct Synthesis of Au, Mn, Pd and Pt_Coated Single Cu Cores and their Assembly into a Superconductor

Synthesis of gold coated copper cores. Initially Cu cores were prepared by adding 5 ml of 1 (mM) Copper(II) chloride (CuCl₂.2H₂O, ACS reagent≥99%) aqueous solution to a mixture of 10 ml 0.1 (M) Cetrimonium bromide (CTAB ACS reagent≥98%) and 40 microlitres of 0.1 (M) KI (ACS reagent≥99%) solution. The pH of this solution was maintained at 7.5 by using an pH meter (Eutech pH Tutor). The CTAB solution was pre-treated with KI to make copper halide clusters which then will turn into desired copper cores upon addition of 2 ml 0.1 (M) ice-cold Sodium Borohydride (NaBH₄ ACS reagent≥98%) solution at 1 min 22 sec. Spectra of such cores are exemplified in FIG. 20j. Then 1 ml of 1 (mM) Hydrogentetrachloroaurate(III)trihydrate (HAuCl₄.3H₂O, ACS 99.99% metal basis) solution was added dropwise over 30 sec to execute the required coating. Further to ensure the reducing environment 1 ml of ice-cold Sodium Borohydride was added to the solution. Now approximately 5 ml IPA (A.R grade) was added to crash the nanoparticles. It was centrifuged, washed once with Acetone (A.R grade) and re-dissolved in CHCl3 (A.R grade) for further processing in making the film. Synthesis of gold coated copper cores. Initially Cu cores were prepared by adding 5 ml of 1 (mM) Copper (II) chloride (CuCl₂.2H₂O, ACS reagent≥99%) aqueous solution to a mixture of 10 ml 0.1 (M) Cetrimonium bromide (CTAB ACS reagent≥98%) and 40 microlitres of 0.1 (M) KI (ACS reagent≥99%) solution. The pH of this solution was maintained at 7.5 by using an pH meter (Eutech pH Tutor). The CTAB solution was pre-treated with KI to make copper halide clusters which then will turn into desired copper cores upon addition of 2 ml 0.1 (M) ice-cold Sodium Borohydride (NaBH₄ ACS reagent≥98%) solution at 1 min 22 sec. Then 1 ml of 1 (mM) Manganese (II) chloride tetrahydrate (MnCl₂.4H₂O, ACS reagent≥98%) solution was added dropwise over 30 sec to execute the required coating. Further to ensure the reducing environment 1 ml of ice-cold Sodium Borohydride was added to the solution. Now approximately 5 ml IPA (A.R grade) was added to crash the nanoparticles. It was centrifuged, washed once with Acetone (A.R grade) and re-dissolved in CHCl3 (A.R grade) for further processing in making the film. Synthesis of palladium coated copper cores. Initially Cu cores were prepared by adding 5 ml of 1 (mM) Copper (II) chloride (CuCl₂.2H₂O, ACS reagent≥99%) aqueous solution to a mixture of 10 ml 0.1 (M) Cetrimonium bromide (CTAB ACS reagent≥98%) and 40 microlitres of 0.1 (M) KI (ACS reagent≥99%) solution. The pH of this solution was maintained at 7.5 by using an pH meter (Eutech pH Tutor). The CTAB solution was pre-treated with KI to make copper halide clusters which then will turn into desired copper cores upon addition of 2 ml 0.1 (M) ice-cold Sodium Borohydride (NaBH₄ ACS reagent≥98%) solution at 1 min 22 sec. Then 1 ml of Potassium tetrachloropalladate (II) (K₂PdCl₄, ACS≥99.99% trace metal basis) solution was added dropwise over 30 sec to execute the required coating. Further to ensure the reducing environment 1 ml of ice-cold Sodium Borohydride was added to the solution. Now approximately 5 ml IPA (A.R grade) was added to crash the nanoparticles. It was centrifuged, washed once with Acetone (A.R grade) and re-dissolved in CHCl3 (A.R grade) for further processing in making the film. Synthesis of platinum coated copper cores. Initially Cu cores were prepared by adding 5 ml of 1 (mM) Copper (II) chloride (CuCl₂.2H₂O, ACS reagent≥99%) aqueous solution to a mixture of 10 ml 0.1 (M) Cetrimonium bromide (CTAB ACS reagent≥98%) and 40 microlitres of 0.1 (M) KI (ACS reagent≥99%) solution. The pH of this solution was maintained at 7.5 by using an pH meter (Eutech pH Tutor). The CTAB solution was pre-treated with KI to make copper halide clusters which then will turn into desired copper cores upon addition of 2 ml 0.1 (M) ice-cold Sodium Borohydride (NaBH₄ ACS reagent≥98%) solution at 1 min 22 sec. Then 1 ml of Chloroplatinic acid hydrate (H₂PtCl₆.xH₂O molecular weight 409.8 anhydrous basis, ACS≥99.9% trace metal basis) solution was added dropwise over 30 sec to execute the required coating. Further to ensure the reducing environment 1 ml of ice-cold Sodium Borohydride was added to the solution. Now approximately 5 ml IPA (A.R grade) was added to crash the nanoparticles. It was centrifuged, washed once with Acetone (A.R grade) and re-dissolved in CHCl3 (A.R grade) for further processing in making the film.

### ADVANTAGES OF THE PRESENT INVENTION

The present invention provides superconductors (blocks, nanocrystals) that can be employed to attain superconductivity at high temperatures, corresponding to temperatures existing in the terrestrial ambient and even higher. This is enabled by the development of a novel nano-architecture that relies on a configuration of cores that are embedded in shells to exhibit superconductivity. This will enable devices to be prepared out of superconductors that can function in the ambient as well as at elevated temperatures.

1. A superconducting block, comprising:
a pair of cores with materials that are electrically conductive in their normal states;
a shell with a material that is electrically conductive in its normal state; and
the pair of cores are embedded in the shell, with an intervening centroidal distance (CD), where the embedded pair of cores and the shell are configured to be superconductive.

2. The superconducting block as claimed in claim 1, wherein each of the cores is with a diameter preferably in the range of 0.3 to 2.7 nanometers.

3. The superconducting block as claimed in claim 1, wherein magnitude of volta potential difference between the materials of the pair of cores and the shell is greater than or equal to ≥0.4V.

4. The superconducting block as claimed in claim 1, wherein the intervening centroidal distance (CD) between at least the pair of cores of, is preferably in the range of 0.7 to 20 nm.

5. The superconducting block as claimed in claim 1, wherein the transition to the superconducting state of the pair of cores and the shell is at a temperature preferably in the range of 1 mK to 10⁴K and at applied pressure preferably in the range of 0-10¹¹ Pa.

6. The superconducting block as claimed in claim 1, wherein the materials are selected from alkali metals, alkaline earth metals, transitional metals, post transitional metals, metalloids and lanthanoids, preferably Lithium (Li) Sodium (Na), Potassium (K), Caesium (Cs), Magnesium (Mg), Beryllium (Be), Calcium (Ca), Strontium (Sr), Barium (Ba), Gold (Au), Copper (Cu), Nickel (Ni), Molybdenum (Mo), strontium (Sr), silver (Ag), Cobalt (Co), Iron (Fe), Niobium (Nb), Zinc (Zn), Tungsten (W), Platinum (Pt), Palladium (Pd), Titanium (Ti), Chromium (Cr), Scandium (Sc), Manganese (Mn), Vanadium (V), Zirconium (Zr), Hafnium (Hf), Cadmium (Cd), Aluminum (Al), Gallium (Ga), Indium (In), Tin (Sn), Lead (Pb), Neodymium (Nd), Tellurium (Te) Antimony (Sb) Bismuth (Bi) or alloys and compounds thereof.

7. The superconducting block as claimed in claim 1, wherein the materials are selected from non-elementary conductors, preferably oxides of metals, doped semiconductors, semi-metals, preferably mercury telluride.

8. The superconducting block as claimed in claim 1, wherein the shell is with multilayers and the pair of cores is with single layer or the pair of cores are with multilayers and the shell is with a single layer, or both shells and the pair of cores are with multilayers.

9. The superconducting block as claimed in claim 1, wherein a plurality of pairs of cores are embedded in the shell and materials of plurality of pairs of cores are non-identical or identical.

10. The superconducting block as claimed in claim 1, wherein the superconducting block is a nanospheroid, nanosphere, nanowire, nanotube, nanocube, nanoplate, nanoplatelet and a nanorod.

11. A superconducting nanocrystal, comprising:
at least a superconducting block, wherein the superconducting block includes
the pair of cores with materials that are electrically conductive in their normal states;
the shell; and
the pair of cores are embedded in the shell, with an intervening centroidal distance (CD), where the embedded pair of cores and the shell are configured to be superconductive.

12. The superconducting nanocrystal as claimed in claim 11, wherein magnetic volume susceptibility of the at least superconducting building block is less than −0.001 SI units.

13. The superconducting nanocrystal as claimed claim 11, wherein a plurality of the superconducting nanocrystals are disposed in a conductive medium with regions and the plurality of the superconducting nanocrystals are not integral to one another.

14. The superconducting nanocrystal as claimed in claim 13, wherein the resistivity of the plurality of the superconducting nanocrystals disposed in the conductive medium, is less than 1×1⁰⁻⁹ Ohm-m.

15. A superconductive device, comprising
at least a superconducting block wherein each of the at least superconducting blocks, include a pair of cores with materials that are electrically conductive in their normal states; a shell with a material that is electrically conductive in its normal state; and the pair of cores are embedded in the shell, with an intervening centroidal distance (CD), where the embedded pair of cores and the shell are configured to be superconductive; and a means to extract or induce currents is connected to the at least superconducting block.

16. The superconductive device as claimed in claim 15, wherein the at least superconducting block is disposed on a substrate.

17. The superconductive device as claimed in claim 16, wherein the material for the substrate is selected from an electrically conducting material, an insulator or a semiconductor.

18. The superconductive device as claimed in claim 16, wherein the material for the substrate is selected from polymer, preferably polyethene, polystyrene, bakelite, rubber, preferably a silicone, nitrile, glass, preferably a borosilicate glass, a metal, preferably copper, iron, nickel or aluminum, or an alloy of the metals, or a combination thereof.

19. The superconductive device as claimed in claim 15, wherein the at least superconducting nanocrystal is used in place of the at least superconducting block.

20. A process for the fabrication of a superconducting block, comprising steps of:
(i) selecting a core material and a shell material, with materials that are electrically conductive in their normal states;
(ii) forming at least a pair of cores of the core material with diameter preferably in the range of 0.3 to 2.7 nanometers; and
(iii) embedding the pair of cores into the shell with intervening centroidal distance (CD) between at least the pair of cores of, wherein the intervening centroidal distance (CD) is preferably in the range of 0.7 to 20 nm, to obtain the superconducting block.

21. The process as claimed in claim 20, wherein a superconducting nanocrystal is prepared from at least a pair of cores and at least a shell.

22. The process as claimed in claim 20, wherein the materials that are electrically conductive in their normal state for the cores and the shells are selected from alkali metals, alkaline earth metals, transitional metals, post transitional metals, metalloids and lanthanoids, preferably Lithium (Li) Sodium (Na), Potassium (K), Caesium (Cs), Magnesium (Mg), Beryllium (Be), Calcium (Ca), Gold (Au), Copper (Cu), Molybdenum (Mo), strontium (Sr), silver (Ag), Cobalt (Co), Iron (Fe), Copper (Cu), Niobium (Nb), Zinc (Zn), Tungsten (W), Platinum (Pt), Palladium (Pd), Silver (Ag), Manganese (Mn), Zinc (Zn), Vanadium (V), Silver (Ag), Zirconium (Zr), Haufnium (Hf), Cadmium (Cd), Aluminum (Al), Lead (Pb), Neodymium (Nd), Tellurium (Te) or alloys thereof.

23. The process as claimed in claim 20, wherein the materials are selected from non-elementary conductors, preferably oxides of metals, doped semiconductors, semi-metals, preferably mercury telluride.

24. The process as claimed in claim 20, wherein magnitude of volta potential difference between the materials of the pair of cores and the shellis greater than or equal to ≥0.4V.

25. The process as claimed in claim 20, wherein the transition to the superconducting state of the pair of cores and the shell is at a temperature preferably in the range of 1 mK to 10⁴K and at applied pressure preferably in the range of 0-10¹¹ Pa.

26. The process as claimed in claim 20, wherein the molar ratios of the materials for the shells and the cores are preferably in the range of 1:20 to 20:1.
